(19) United States
(12) Patent Application Publication
(10) Pub. No.: US 2025/0282908 A1
(43) Pub. Date: Sep. 11, 2025

(54) FLUX AGENT AND SEMICONDUCTOR PACKAGE INCLUDING CURED PRODUCT THEREOF

(71) Applicant: ELECTRONICS AND TELECOMMUNICATIONS RESEARCH INSTITUTE, Daejeon (KR)

(72) Inventors: Gwang-Mun CHOI, Daejeon (KR); Jungho SHIN, Daejeon (KR); Yong Sung EOM, Daejeon (KR); Jiho JOO, Daejeon (KR); Kwang-Seong CHOI, Daejeon (KR); Seok-Hwan MOON, Daejeon (KR); Jin Hyuk OH, Daejeon (KR); Chanmi LEE, Daejeon (KR); Ki Seok JANG, Daejeon (KR)

(21) Appl. No.: 19/075,456

(22) Filed: Mar. 10, 2025

(30) Foreign Application Priority Data
Mar. 11, 2024 (KR) 10-2024-0033871
Mar. 7, 2025 (KR) 10-2025-0030023

(51) Int. Cl. C08G 59/68; H01L 23/00

(52) U.S. Cl. CPC C08G 59/686; H01L 24/13; H01L 24/16; H01L 2224/1379; H01L 2224/13999; H01L 2224/16059; H01L 2224/16227; H01L 2224/16238; H01L 2924/182

(57) ABSTRACT

Provided is a flux agent according to embodiments of the inventive concept, wherein the flux agent includes a first compound including an ester group and an epoxy group, a fourth compound which is a chemical reactant of a second compound including an epoxy group and a third compound including an amine group and a carboxyl group, and a photoinitiator, wherein the content of the first compound is 50 wt % to 60 wt % based on 95 wt % of the total agent, the content of the fourth compound is 3 wt % to 33 wt % based on 100 wt % of the total agent, and the content of the photoinitiator is 2 wt % to 10 wt % based on 100 wt % of the total agent.

### CROSS-REFERENCE TO RELATED APPLICATIONS

This U.S. non-provisional patent application claims priority under 35 U.S.C. § 119 of Korean Patent Application Nos. 10-2024-0033871, filed on Mar. 11, 2024, and 10-2025-0030023, filled on Mar. 7, 2025, the entire contents of which are hereby incorporated by reference.

### BACKGROUND

The present disclosure herein relates to a flux agent and a semiconductor package including a cured product of the flux agent.

Electronic devices have become smaller and more multi-functional according to the rapid development of the electronics industry and the demands of users. Accordingly, there is also an increasing need for semiconductor devices used in electronic devices to be small and multi-functional.

### SUMMARY

The present disclosure provides a flux agent for performing various functions.

The present disclosure also provides a method for manufacturing a semiconductor package with reduced difficulty of a manufacturing process.

A flux agent according to embodiments of the inventive concept comprises a first compound comprising an ester group and an epoxy group, a fourth compound which is a chemical reactant of a second compound comprising an epoxy group and a third compound comprising an amine group and a carboxyl group, and a photoinitiator, wherein the content of the first compound is 60 wt % to 95 wt % based on 100 wt % of the total agent, the content of the fourth compound is 3 wt % to 33 wt % based on 100 wt % of the total agent, and the content of the photoinitiator is 2 wt % to 10 wt % based on 100 wt % of the total agent.

A semiconductor package according to some embodiments of the inventive concept comprises a semiconductor substrate comprising an upper surface and a lower surface which are opposite to each other, a semiconductor chip comprising a first surface and a second surface which are opposite to each other, and disposed on the upper surface of the semiconductor substrate, wherein the first surface faces the upper surface of the semiconductor substrate, and a plurality of protective patterns interposed between the semiconductor substrate and the semiconductor chip, wherein each of the plurality of protective patterns is a cured product of a flux agent, wherein the flux agent comprises a first compound comprising an ester group and an epoxy group, a fourth compound which is a chemical reactant of a second compound comprising an epoxy group and a third compound comprising an amine group and a carboxyl group, and a photoinitiator, wherein the content of the first compound is 60 wt % to 95 wt % based on 100 wt % of the flux agent, the content of the fourth compound is 3 wt % to 33 wt % based on 100 wt % of the flux agent, and the content of the photoinitiator is 2 wt % to 10 wt % based on 100 wt % of the flux agent.

A semiconductor package according to some embodiments of the inventive concept comprises a semiconductor substrate comprising an upper surface and a lower surface which are opposite to each other, a plurality of first conductive pads on the upper surface of the semiconductor substrate, a semiconductor chip including a first surface and a second surface which are opposite to each other, and disposed on the upper surface of the semiconductor substrate, wherein the first surface faces the upper surface of the semiconductor substrate, a plurality of second conductive pads on the first surface of the semiconductor chip, a plurality of connecting bumps interposed between the plurality of first conductive pads and the plurality of second conductive pads, and a plurality of protective patterns covering the plurality of connecting bumps, wherein a width in a first direction of each of the plurality of protective patterns decreases in a third direction farther from the upper surface of the semiconductor substrate, wherein the first direction is a direction parallel to the upper surface of the semiconductor substrate, wherein the third direction is a direction perpendicular to the upper surface of the semiconductor substrate.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a plan view of a semiconductor package according to embodiments of the inventive concept;

FIG. 2 is a cross-sectional view taken along A-A′ of FIG. 1;

FIG. 3 to FIG. 8 are views showing a method for manufacturing a semiconductor package according to embodiments of the inventive concept, and are cross-sectional views corresponding to A-A′ of FIG. 1;

FIG. 9 to FIG. 14 are views showing a method for manufacturing a semiconductor package according to some embodiments of the inventive concept, and are cross-sectional views corresponding to A-A′ of FIG. 1;

FIG. 15 is a cross-sectional view of a semiconductor package according to some embodiments of the inventive concept, and are cross-sectional views taken along A-A′ of FIG. 1;

FIG. 16 to FIG. 19 are views showing a method for manufacturing a semiconductor package according to some embodiments of the inventive concept, and are cross-sectional views corresponding to A-A′ of FIG. 1;

FIG. 20 is a cross-sectional view of a semiconductor package according to some embodiments of the inventive concept, and are cross-sectional views taken along A-A′ of FIG. 1;

FIG. 21 to FIG. 25 are views showing a method for manufacturing a semiconductor package according to some embodiments of the inventive concept, and are cross-sectional views corresponding to A-A′ of FIG. 1;

FIG. 26 is a cross-sectional view according to some embodiments of the inventive concept, and is a cross-sectional view taken along line A-A′ of FIG. 1;

FIG. 27 is a plan view of a semiconductor package according to some embodiments of the inventive concept;

FIG. 28 is a cross-sectional view of a semiconductor package according to some embodiments of the inventive concept, and is a cross-sectional view taken along A-A′ of FIG. 27;

FIG. 29 is a plan view of a semiconductor package according to some embodiments of the inventive concept;

FIG. 30 is a cross-sectional view of a semiconductor package according to some embodiments of the inventive concept, and is a cross-sectional view taken along A-A′ of FIG. 29;

FIG. 31A and FIG. 31B are results of photographing a semiconductor chip and a semiconductor substrate using a scanning electron microscope;

FIG. 32 is result of photographing a protection pattern according to an embodiment formed on a semiconductor chip using a scanning electron microscope; and

FIG. 33 is result of photographing a cross-section of a junction according to an embodiment using a scanning electron microscope;

### DETAILED DESCRIPTION

Throughout the present specification, reference to “one embodiment” or “an embodiment” means that a particular feature, structure, or characteristic described in connection with the embodiment may be included in at least one embodiment disclosed herein. Therefore, in various places throughout the present specification, the appearances of phrases “in one embodiment,” “in an embodiment,” or “according to an embodiment” (or other phrases with similar meanings) do not necessarily all refer to the same embodiment. In addition, particular features, structures, or characteristics may be combined in any suitable manner in one or more embodiments. In this regard, as used herein, the word “exemplary” means “providing an example, exemplification, or illustration.” Any embodiment described herein as “exemplary” is not necessarily to be construed as preferred or advantageous over other embodiments. In addition, depending on the context of the discussion herein, a singular term may include a corresponding plural form, and a plural term may include a corresponding singular form. It should be noted that the various drawings (including block configuration diagram) shown and discussed herein are for illustrative purposes only, and are not drawn to scale.

In the present specification, unless otherwise defined, a particle diameter may be an average particle diameter. In addition, the particle diameter refers to an average particle diameter (D₅₀) meaning a diameter of a particle having a cumulative volume of 50 vol % in a particle size distribution. The average particle diameter (D₅₀) may be measured by a method widely known to those skilled in the art, for example, by using a particle size analyzer, or using a transmission electron microscope (TEM) photograph or scanning electron microscope (SEM) photograph. As another method, a measurement device using dynamic light-scattering may be used to perform measurement, the number of particles for each particle size range may be counted by performing data analysis, and then an average particle diameter (D₅₀) value may be obtained by performing calculated therefrom. Alternatively, the average particle diameter (D₅₀) may be measured by a laser diffraction method. More specifically, when the measurement is performed by a laser diffraction method, particles to be measured may be dispersed in a dispersion medium, introduced into a commercially available laser diffraction particle diameter measurement device (e.g., MT 3000 manufactured by Microtrac Co., Ltd.), and then irradiated with an ultrasonic wave of about 28 kHz to an output of 60 W to calculate an average particle diameter (D₅₀) at 50% of a particle diameter distribution in the measurement device.

Hereinafter, embodiments of the inventive concept will be described with reference to the accompanying drawings to describe the inventive concept in detail.

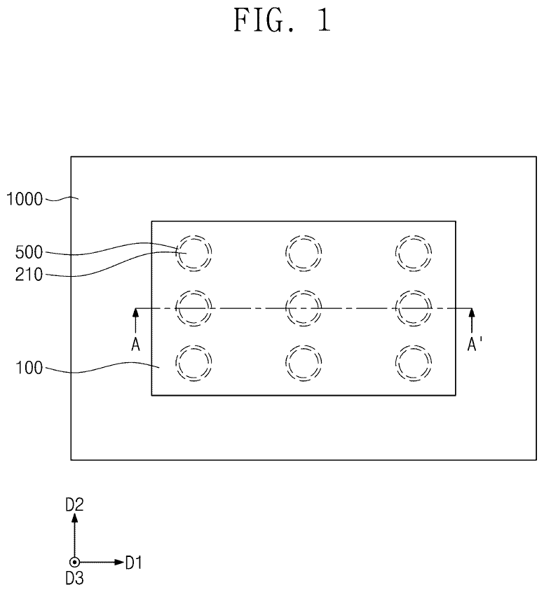

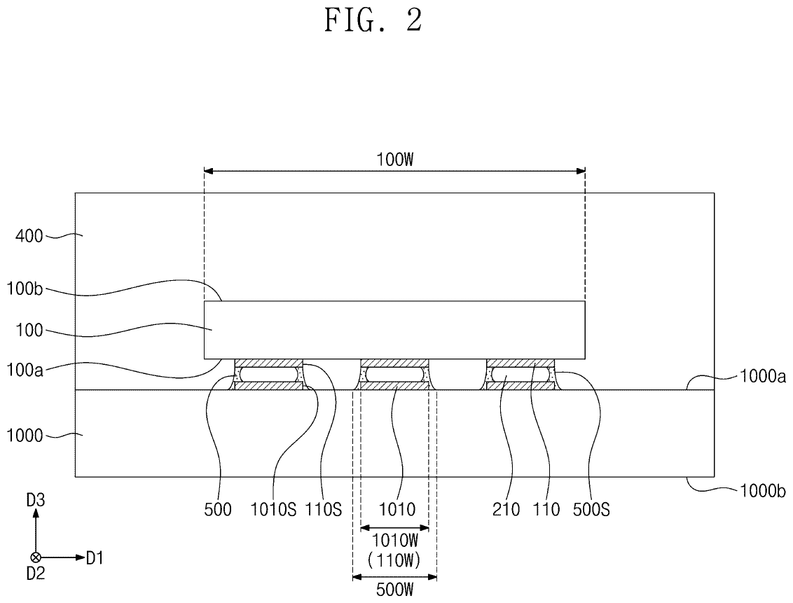

FIG. 1 is a plan view of a semiconductor package according to embodiments of the inventive concept. FIG. 2 is a cross-sectional view taken along A-A′ of FIG. 1.

Referring to FIG. 1 and FIG. 2, a semiconductor substrate 1000 including an upper surface 1000a and a lower surface 1000b which are opposite to each other may be provided. The semiconductor substrate 1000 may be, for example, a printed circuit board (PCB), a silicon substrate, glass substrate.

A plurality of first conductive pads 1010 may be disposed on the upper surface 1000a of the semiconductor substrate 1000. The plurality of first conductive pads 1010 may be spaced apart from each other in a first direction D1 and a second direction D2.

In the present specification, the first direction D1 may be a direction parallel to the upper surface 1000a of the semiconductor substrate 1000. The second direction D2 may be a direction parallel to the upper surface 1000a of the semiconductor substrate 1000 and intersecting the first direction D1. The third direction D3 may be a direction perpendicular to the upper surface 1000a of the semiconductor substrate 1000.

The plurality of first conductive pads 1010 may include, for example, one or more selected from the group consisting of copper (Cu), aluminum (Al), tungsten (W), titanium (Ti) nickel (Ni), gold (Au), and an alloy thereof. The disposition and number of the plurality of first conductive pads 1010 may not be limited to that illustrated in FIG. 1. The plurality of first conductive pads 1010 may be fewer than nine, or may be provided more than nine.

A semiconductor chip 100 including a first surface 100a and a second surface 100b which are opposite to each other may be provided on the upper surface 1000a of the semiconductor substrate 1000. The first surface 100a of the semiconductor chip 100 may face the upper surface 1000a of the semiconductor substrate 1000. The semiconductor chip 100 may include, for example, one or more among a passive element, an active element, a light emitting diode, a memory chip, and a logic chip. The semiconductor chip 100 may include, for example, a volatile memory semiconductor chip such as a dynamic random access memory (DRAM) or a static random access memory (SRAM).

The semiconductor chip 100 may include, for example, a non-volatile memory semiconductor chip such as a flash memory, a phase-change random access memory (PRAM), a magnetic random access memory (MRAM), a ferroelectric random access memory (FeRAM), or a resistive random access memory (RRAM).

A plurality of second conductive pads 110 may be disposed on the first surface 100a of the semiconductor chip 100. Each of the plurality of second conductive pads 110 may be disposed to correspond to each of the plurality of first conductive pads 1010. The plurality of second conductive pads 110 may include, for example, one or more selected from the group consisting of copper (Cu), aluminum (Al), tungsten (W), titanium (Ti) nickel (Ni), gold (Au), and an alloy thereof.

A plurality of connecting bumps 210 may be interposed between the plurality of first conductive pads 1010 and the plurality of second conductive pads 110.

Each of the plurality of connecting bumps 210 may be interposed between corresponding first and second conductive pads among the plurality of first and second conductive pads 1010 and 110. Accordingly, the first and second conductive pads 1010 and 110 may be electrically connected to each other, and the semiconductor substrate 1000 and the semiconductor chip 100 may be electrically connected to each other. The plurality of connecting bumps 210 may be, for example, solder.

A plurality of protective patterns 500 may be interposed between the semiconductor chip 100 and the semiconductor substrate 1000. The plurality of protective patterns 500 may come into contact with the upper surface 1000a of the semiconductor substrate 1000 and the first surface 100a of the semiconductor chip 100. The plurality of protective patterns 500 may be spaced apart from each other in the first direction D1 and the second direction D2.

The plurality of protective patterns 500 may cover the plurality of first and second conductive pads 1010 and 110 and the connecting bumps 210. More specifically, each of the plurality of protective patterns 500 may cover a side surface 1010S of a corresponding first conductive pad and a side surface 110S of a corresponding second conductive pad. Each of the plurality of protective patterns 500 may form, for example, a closed curve when viewed in a plan view. The plurality of protective patterns 500 may protect the plurality of first and second conductive pads 1011 and 110, and the plurality of connecting bumps 210 from external impurities and impacts.

A width 500 W of each of the plurality of protective patterns 500 in the first direction D1 may be smaller than a width 100 W of the semiconductor chip 100 in the first direction D1. The width 500 W of each of the plurality of protective patterns 500 in the first direction D1 may decrease in the third direction D3 farther from the upper surface 1000a of the semiconductor substrate 1000. The width 500 W of each of the plurality of protective patterns 500 in the first direction D1 may increase closer to the upper surface 1000a of the semiconductor substrate 1000. The width 500 W of each of the plurality of protective patterns 500 in the first direction D1 may decrease closer to the first surface 100a of the semiconductor chip 100. A maximum width of each of the plurality of protective patterns 500 in the first direction D1 may be larger than a width 110 W of each of the plurality of first conductive pads 1010 in the first direction D1.

The plurality of protective patterns 500 may be a cured product of a flux agent. The flux agent may include a first compound including an ester group and an epoxy group, a fourth compound, and a photoinitiator.

The content of the first compound may be 60 wt % to 95 wt % based on 100 wt % of the flux agent. If the content of the first compound satisfies the above-described numerical range, the formation of the protective pattern 500 on the semiconductor chip 100, the semiconductor substrate 1000, the plurality of first and second conductive pads, and connecting bumps may effectively performed and after curing the protective pattern 500 may allow sufficient fluidity during the bonding process.

The first compound may include at least one of glycidyl epoxy and cyclohexene oxide. The first compound may include, for example, one or more selected from the group consisting of Methyl 3-(7-oxabicyclo[4.1.0]heptan-3-yl)-7-oxabicyclo[4.1.0]heptane-3-carboxylate, (5-Methyl-7-oxabicyclo[4.1.0]heptan-3-yl)methyl 5-methyl-7-oxabicyclo[4.1.0]heptane-3-carboxylate, [2,2-Dimethyl-3-(6-methyl-7-oxabicyclo[4.1.0]heptane-3-carbonyl)oxypropyl] 6-methyl-7-oxabicyclo[4.1.0]heptane-3-carboxylate, (1-Methyl-7-oxabicyclo[4.1.0]heptan-3-yl)methyl 1-methyl-7-oxabicyclo[4.1.0]heptane-3-carboxylate, 7-Oxabicyclo[4.1.0]heptan-2-ylmethyl 7-oxabicyclo[4.1.0]heptane-3-carboxylate, 6-(7-Oxabicyclo[4.1.0]heptan-1-ylmethyl)-7-oxabicyclo[4.1.0]heptane-3-carboxylate, (2-Methyl-7-oxabicyclo[4.1.0]heptan-3-yl)methyl 2-methyl-7-oxabicyclo[4.1.0]heptane-3-carboxylate, 2-(7-Oxabicyclo[4.1.0]heptan-3-yl) ethyl 7-oxabicyclo[4.1.0]heptane-3-carboxylate, 2-[2-(7-Oxabicyclo[4.1.0]heptane-3-carbonyloxy)ethoxy]ethyl 7-oxabicyclo[4.1.0]heptane-3-carboxylate, Bis(7-oxabicyclo[4.1.0]heptan-3-ylmethyl) heptanedioate, 3,4-Epoxycyclohexylmethyl 3,4-epoxycyclohexanecarboxylate, Bis(3,4-epoxycyclohexylmethyl) adipate, Chissonox 3-[2-(3-Carboxylato-7-oxabicyclo[4.1.0]heptan-3-yl)ethyl]-7-201, oxabicyclo[4.1.0]heptane-3-carboxylate, 2-(7-Oxabicyclo[4.1.0]heptane-3-carbonyloxy) ethyl 7-oxabicyclo[4.1.0]heptane-3-carboxylate, 3,4-Epoxycyclohexyl-3,4-epoxycyclo-hexane carboxylate, 5-Methyl-3-[(5-methyl-7-oxabicyclo[4.1.0]heptan-3-yl)methyl]-7-oxabicyclo[4.1.0]heptane-3-carboxylate, 1,4-Cyclohexanedimethanol bis(3,4-epoxycyclohexanecarboxylate), Cyclohexylmethyl-3,4-epoxycyclohexanecarboxylate, Glycidyl methacrylate, Ethyl 2,3-epoxybutyrate, Methyl 3,4-epoxybutyrate, Ethyl oxirane-2-carboxylate, Glycidyl butyrate, (2-Methyloxiranyl)methyl methacrylate, 9,10-Epoxystearate, Diglycidyl isophthalate, oxiran-2-ylmethyl benzoate, Tris(oxiranylmethyl)benzene-1,3,5-tricarboxylate, Bis(2,3-epoxypropyl) terephthalate, Bis(oxiran-2-ylmethyl) 5-carbonochloridoylbenzene-1,3-dicarboxylate, and a combination thereof.

The content of fourth compound may be 3 wt % to 33 wt % based on 100 wt % of the flux agent. The fourth compound may be a chemical reactant of a second compound including an epoxy group and a third compound including an amine group and a carboxyl group.

If the content of the fourth compound satisfies the above-described numerical range, a metal oxide on the semiconductor chip 100, the semiconductor substrate 1000, and the plurality of first and second conductive pads may be effectively removed, and the formation of the protective pattern may be effectively performed. For example, if the content of the fourth compound is less than 3 wt % a metal oxide may not be removed effectively, the content of the fourth compound is greater than 33 wt % the protective pattern may not be formed effectively.

The fourth compound may include a covalent bond formed by the reaction between the epoxy group of the second compound and the amine group of the third compound. The fourth compound may include a covalent bond formed by the reaction between the epoxy group of the second compound and the carboxyl group of the third compound. The fourth compound may not be a simple mixture of the second compound and the third compound, and may be a chemical reactant of the second compound and the third compound. As an example, the fourth compound may be easily dissolved in an organic solvent.

The second compound may include, for example, at least one of glycidyl epoxy and cyclohexene oxide. The second compound may comprise, for example, an epoxy siloxane resin. The second compound may comprise, for example, one or more selected from the group consisting of 3-Glycidoxypropyltrimethoxysilane, 3-Glycidoxypropyltriethoxysilane, (3-Glycidoxypropyl)methyldiethoxysilane, (3-Glycidoxypropyl)methyldimethoxysilane, β-(3,4-Epoxycyclohexyl)ethyltrimethoxysilane, β-(3,4-Epoxycyclohexyl)ethyltriethoxysilane, 3,4-Epoxycyclohexylmethyl 3,4-epoxycyclohexanecarboxylate, Bis(3,4-epoxycyclohexylmethyl) adipate, and a combination thereof.

The third compound may include one or more selected from the group consisting of alpha (a)-amino acid, beta (B)-amino acid, gamma (γ)-amino acid, delta (8)-amino acid, anthranilic acid, 3-aminobenzoic acid, para-aminobenzoic acid, and a combination thereof. The third compound may include, for example, may include one or more selected from the group consisting of selected from glycine, alanine, valine, leucine, isoleucine, lysine, arginine, histidine, aspartic acid, asparagine, glutamine, glutamic acid, phenylalanine, tyrosine, tryptophan, cysteine, methionine, serine, ornithine, 3-phenylserine, threonine, L-dopa, norleucine, penicillamine, sarcosine, proline, hydroxyproline, 3-hydroxyproline, 3,4-dihydroproline, pipecolic acid, β-alanine, 3-aminobutyric acid, isoserine, 3-aminoisobutyric acid, 3-amino-2-phenylpropionic acid, 3-amino-5-methylhexanoic acid, 3-amino-4-phenylbutyric acid, 3-amino-4-hydroxybutyric acid, 3-amino-4-hydroxypentanoic acid, 3-amino-4-methylpentanoic acid, 3-amino-3-phenylpropionic acid, pyrrolidine-3-carboxylic acid, y-aminobutyric acid, 4-amino-3-hydroxybutyric acid, 3-pyrrolidine-2-yl-propionic acid, 3-aminocyclohexanecarboxylic acid, 4-guanidinobutyric acid, 4-aminobenzoic acid, 3-aminobenzoic acid, 2-aminobenzoic acid, 3,5-diaminobenzoic acid, 4-aminosalicylic acid, 5-aminosalicylic acid, 3-aminoisonicotinic acid, 4-aminonicotinic acid, 5-aminonicotinic acid, 2-aminonicotinic acid, 6-aminonicotinic acid, 2-aminoisonicotinic acid, 6-aminopicolinic acid, a combination thereof, and a chemical reactant thereof.

The content of the photoinitiator may be 2 wt % to 10 wt % based on 100 wt % of the flux agent. If the content of the photoinitiator is less than 2 wt %, a photo-curing reaction may not effectively occur. If the content of the photoinitiator is greater than 10 wt %, a metal oxide on the plurality of first and second conductive pads 1010 and 110 and the plurality of connecting bumps 210 may not be effectively removed.

The photoinitiator may initiate a curing reaction of the first compound including an ester group of the first compound by light energy or heat energy. The photoinitiator may form, for example, cations by light energy or heat energy, and may initiate the curing reaction through the cations.

The photoinitiator may include, for example, at least one selected from the group consisting of an onium salt (e.g., an iodonium salt, a sulfonium salt, a phosphonium salt, a diazonium salt, a pyridinium salt, or an imide) such as 3-methyl-2-butenyltetramethylenesulfonium hexafluoroantimonate salt, ytterbium trifluoromethanesulfonate salt, samarium trifluoromethanesulfonate salt, erbium trifluoromethanesulfonate salt, triarylsulfonium hexafluoroantimonate salt, triarylsulfonium hexafluorophosphate salt, lanthanum trifluoromethanesulfonate salt, tetrabutylphosphonium methensulfonate salt, ethyltriphenylphosphonium bromide salt, diphenyldiodonium hexafluoroantimonate salt, diphenyldiodonium hexafluorophosphate salt, dithoriliodonium hexafluorophosphate salt, 9-(4-hydroxyethoxyphenyl)cyanthrhenium hexafluorophosphate salt, and 1-(3-methylbut-2-enyl) tetrahydro-1H-thiophenium hexafluoroantimonate salt, 2-(9-oxoxanthen-2-yl) propionic acid 1,5,7-triazabicyclo[4.4.0]dec-5-ene salt, and a combination thereof.

The flux agent may further include a catalyst, a solvent, a leveling agent, and metal nanoparticles. The catalyst may include, for example, one or more selected from the group consisting of a base such as 1,5,7-triazabicyclo[4.4.0]dec-5-ene, 2-methylimidazole, and 1-methylimidazole, a Lewis acid such as zinc acetate, a phosphine such as triphenylphosphine, dibutyl phosphate, and a combination thereof.

The solvent may be, for example, an organic solvent, for example, one or more among acetone, benzene, toluene, hexane, methanol, dichloromethane, ethyl acetate, γ-Butyrolactone, Cyclopentanone, Propylene Glycol Monomethyl Ether, Propylene Glycol Monomethyl Ether Acetate and diethyl ether.

The metal nanoparticles may contain one or more among a metal such as tin (Sn), copper (Cu), silver (Ag), bismuth (Bi), indium (In), lead (Pd), cadmium (Cd), antimony (Sb), gallium (Ga), arsenic (As), germanium (Ge), zinc (Zn), aluminum (Al), gold (Au), silicon (Si), nickel (Ni), and phosphorus (P), a non-metal, and an alloy selected from a combination thereof. The average particle diameter of the metal nanoparticles may be, for example, 0.01 μm to 1 μm.

A molding film 400 may be disposed on the upper surface 1000a of the semiconductor substrate 1000. The molding film 400 may cover the semiconductor chip 100, and may fill a space between the plurality of protective patterns 500. The molding film 400 may come into contact with the upper surface 1000a of the semiconductor substrate 1000, and may come into contact with the first surface 100a of the semiconductor chip 100. The molding film 400 may come into contact with a side surface 500S of the plurality of protective patterns 500. The molding film 400 may include, for example, an epoxy molding compound, molded underfill. The molding film 400 may protect the semiconductor package from impurities, and external impacts.

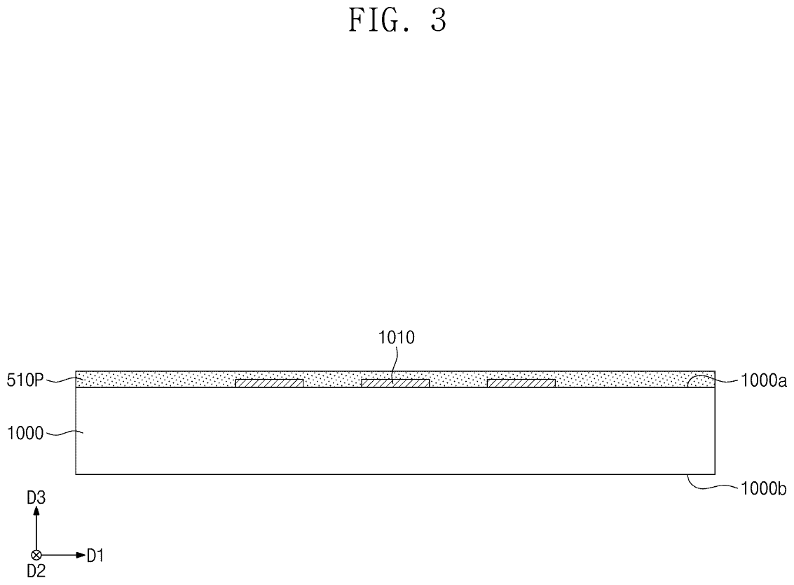

FIG. 3 to FIG. 8 are views showing a method for manufacturing a semiconductor package according to embodiments of the inventive concept, and are cross-sectional views corresponding to A-A′ of FIG. 1. In order to simplify the description, the same descriptions as those of the semiconductor package described with reference to FIG. 1 and FIG. 2 will be omitted.

Referring to FIG. 3, a flux agent 510P may be prepared. The preparing of the flux agent 510P may include, for example, mixing a first compound, a fourth compound, and a photoinitiator in a solvent. As an example, the fourth compound may be easily dissolved in an organic solvent. The content of the first compound may be 60 wt % to 95 wt % based on 100 wt % of the flux agent. The first compound may include at least one of glycidyl epoxy and cyclohexene oxide.

The content of fourth compound may be 3 wt % to 33 wt % based on 100 wt % of the flux agent. The fourth compound may be a chemical reactant of a second compound including an epoxy group and a third compound including an amine group and a carboxyl group. The second compound may include, for example, at least one of glycidyl epoxy and cyclohexene oxide. The second compound may include, for example, an epoxy siloxane resin. The forming of the fourth compound may include, for example, mixing the second compound and the third compound at room temperature, and reacting the second compound and the third compound at 150° C. to 300° C. for 30 minutes to 24 hours. The content of the photoinitiator may be 2 wt % to 10 wt % based on 100 wt % of the flux agent. The flux agent may further include a catalyst, a solvent, a leveling agent, and metal nanoparticles.

A plurality of first conductive pads 1010 may be formed on an upper surface 1000a of a semiconductor substrate 1000. The flux agent 510P may be formed on the upper surface 1000a of the semiconductor substrate 1000. The flux agent 510P may cover the upper surface 1000a of the semiconductor substrate 1000, and may cover a plurality of first conductive pads 1010 on the semiconductor substrate 1000. The flux agent 510P may conformally cover side surfaces and upper surfaces of the plurality of first conductive pads 1010. The forming of the flux agent 510P on the upper surface 1000a of the semiconductor substrate 1000 may include, for example, a spin coating process.

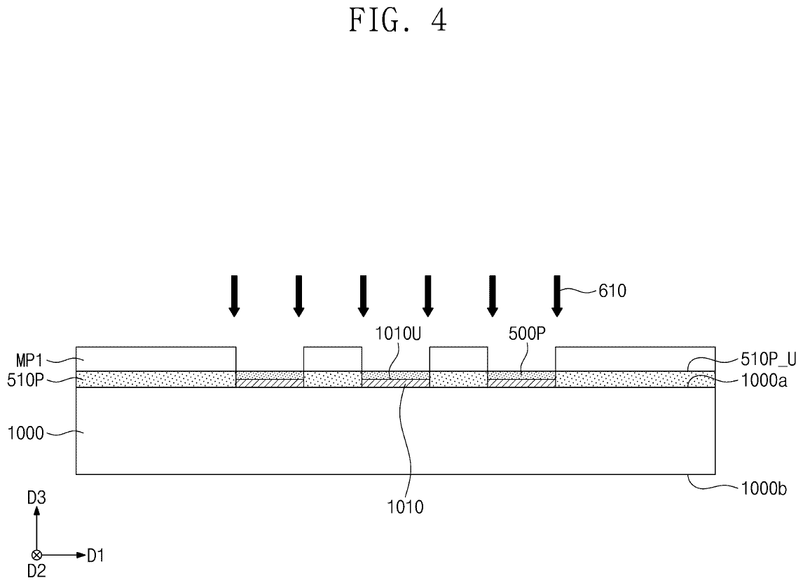

Referring to FIG. 4, a plurality of preliminary protective patterns 500P may be formed. The plurality of preliminary protective patterns 500P may be formed on the plurality of first conductive pads 1010. The forming of the plurality of preliminary protective patterns 500P may include, for example, forming a first mask pattern MP1 on the flux agent 510P, wherein the first mask pattern MP1 exposes an upper surface 510P_U of the flux agent 510P corresponding to an upper surface 1010U of each of the plurality of first conductive pads 1010, and curing the flux agent by irradiating the exposed upper surface 510P_U of the flux agent 510P with light or heat energy 610.

By the light energy or heat energy, a curing reaction by the photoinitiator may occur. A curing reaction of the first compound of the flux agent 510P may occur. Accordingly, the flux agent 510P may be cured. The light energy may include, for example, light (e.g., ultraviolet light) having a wavelength of 10 nm to 600 nm.

According to the embodiments of the inventive concept, the plurality of preliminary protective patterns 500P, which are cured products of the flux agent 510P, may be formed on the plurality of first conductive pads 1010. Each of the plurality of preliminary protective patterns 500P may be in a solid state at room temperature.

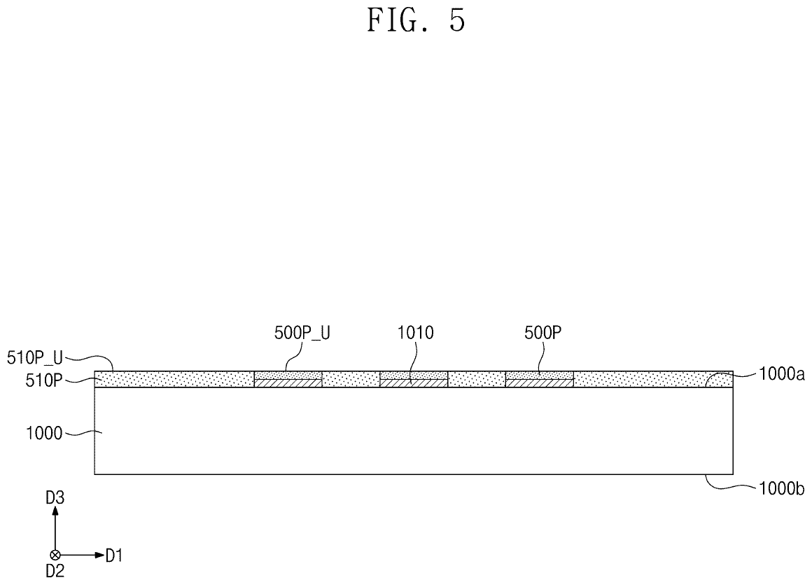

Referring to FIG. 5, the first mask pattern MP1 may be removed. An upper surface 500P_U of the plurality of preliminary protective patterns 500P and the upper surface 510P_U of the flux agent 510P may be exposed.

The plurality of preliminary protective patterns 500P may be disposed on the plurality of first conductive pads 1010. The flux agent 510P may cover a side surface of each of the plurality of preliminary protective patterns 500P, and a side surface of each of the plurality of first conductive pads 1010.

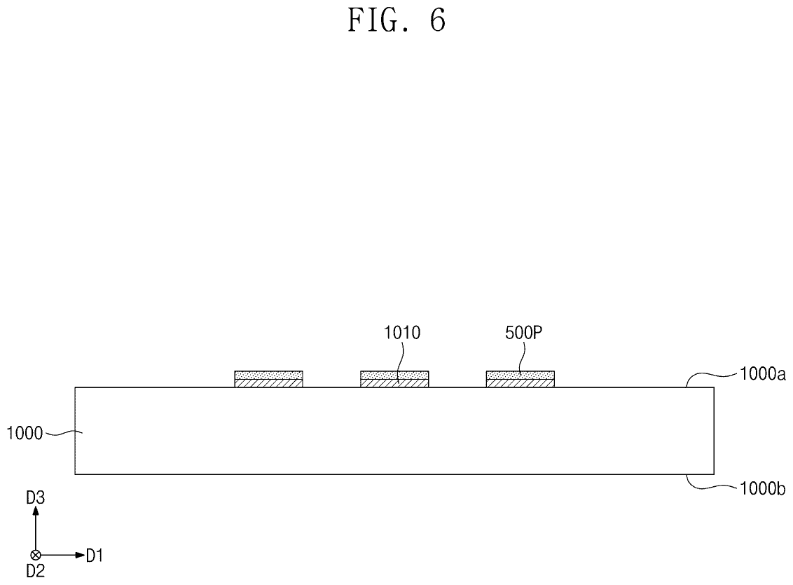

Referring to FIG. 6, the flux agent 510P may be removed. The plurality of preliminary protective patterns 500P are in a solid state, and may not be removed. The upper surface 1000a of the semiconductor substrate 1000 may be exposed, and the side surfaces of the plurality of first conductive pads 1010 and the plurality of preliminary protective patterns 500P may be exposed. Furthermore, a defect in which the plurality of preliminary protective patterns 500P flow or evaporate during a process may not occur. The semiconductor substrate 1000 on which the plurality of preliminary protective patterns 500P are formed may be stored for a long period of time. Application fixation of the flux agent 510P and a bonding process to be described later may be spatially and temporally dualized. Accordingly, a method for manufacturing various semiconductor packages may be applied. In addition, prior to a bonding process of the semiconductor substrate 1000 and a semiconductor chip 100, the plurality of first conductive pads 1010 may be physically and chemically protected by the plurality of preliminary protective patterns 500P.

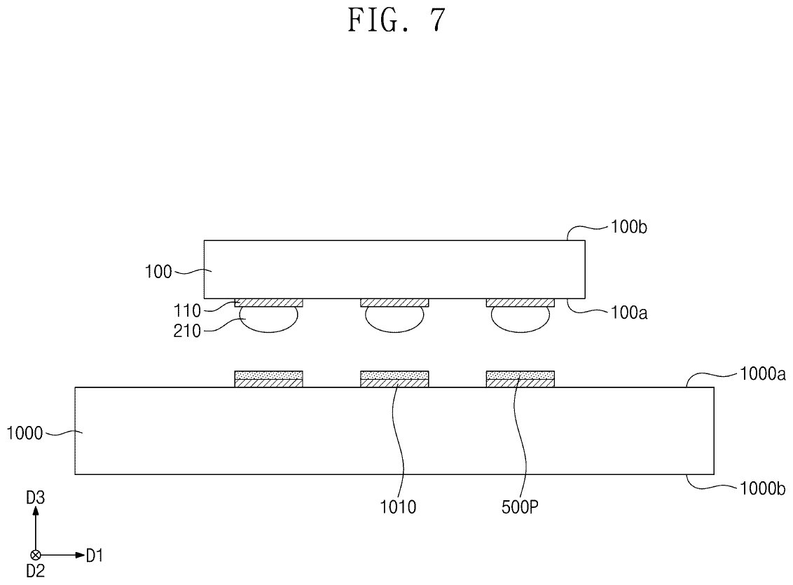

Referring to FIG. 7, a plurality of second conductive pads 110 and a plurality of connecting bumps 210 may be formed on a first surface 100a of the semiconductor chip 100. Each of the plurality of connecting bumps 210 may be formed on a corresponding second conductive pad among the plurality of second conductive pads 110.

The first surface 100a of the semiconductor chip 100 may be provided to face the upper surface 1000a of the semiconductor substrate 1000. Each of the plurality of second conductive pads 110 and the plurality of connecting bumps 210 may be provided to correspond to a corresponding first conductive pad 1010 and a corresponding preliminary protective pattern 500P.

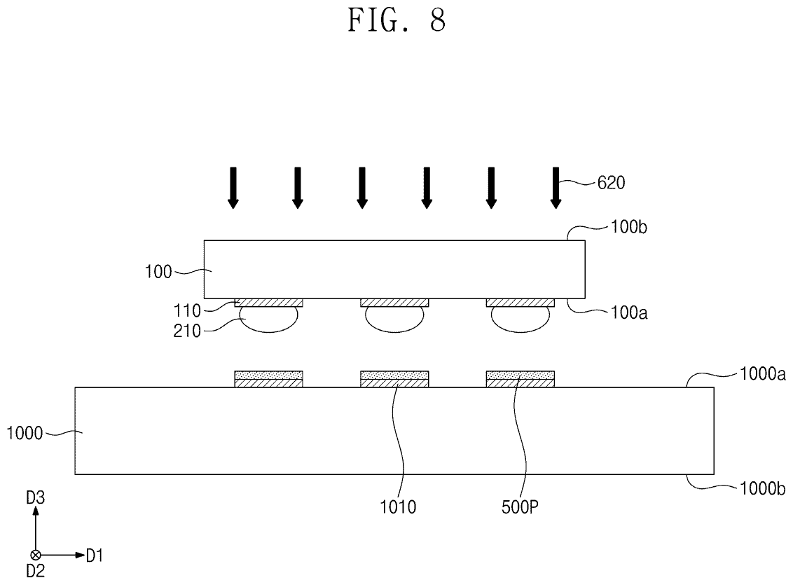

Referring to FIG. 8, a bonding process 620 may be performed. The bonding process 620 may include applying pressure to the semiconductor chip 100 and the semiconductor substrate 1000 which are aligned. The bonding process 620 may include applying pressure to the semiconductor chip 100 and the semiconductor substrate 1000, and applying light energy or heat energy to the plurality of preliminary protective patterns 500P.

Referring back to FIG. 1 and FIG. 2, the semiconductor chip 100 and the semiconductor substrate 1000 may be bonded to each other by the bonding process. The plurality of first conductive pads 1010, the plurality of second conductive pads 110, and the plurality of connecting bumps 210 may be electrically connected to each other. Accordingly, the semiconductor chip 100 and the semiconductor substrate 1000 may be electrically connected to each other.

A plurality of protective patterns 500 may be formed. The forming of the plurality of protective patterns 500 may include, through the above-described bonding process, applying pressure to the plurality of preliminary protective patterns 500P, and applying heat or light energy to the plurality of preliminary protective patterns 500P. The light energy may comprise, for example, a laser having a wavelength of 600 nm to 3000 nm and microwave having a wavelength of 1 mm to 1 m.

Due to the heat energy or light energy in the bonding process, the plurality of preliminary protective patterns 500P may have fluidity. The plurality of preliminary protective patterns 500P may be pushed to side surfaces of the plurality of first and second conductive pads 1010 and 110 and the plurality of connecting bumps 210. Due the above-described fluidity, a width 500 W of each of the plurality of preliminary protective patterns 500P in a first direction D1 may decrease in a third direction D3 farther from the upper surface 1000a of the semiconductor substrate 1000.

Furthermore, due to the heat energy or light energy, the fourth compound in the plurality of preliminary protective patterns 500P may act as a reducing agent. Accordingly, a metal oxide on the plurality of connecting bumps 210 may be removed, and defects due to impurities during the bonding process may be removed.

The plurality of protective patterns 500 may cover some or all of side surfaces 1010S, 110S, and 500S of the plurality of first and second conductive pads 1010 and 110 and the plurality of connecting bumps 210, and may protect the plurality of first and second conductive pads 1010 and 110 and the plurality of connecting bumps 210.

According to the embodiments of the inventive concept, the plurality of preliminary protective patterns 500P may function as a flux agent for removing the metal oxide on the plurality of connecting bumps, and serve to protect the plurality of connecting bumps during a semiconductor manufacturing process.

A molding film 400 may be formed on the upper surface 1000a of the semiconductor substrate 1000. The molding film 400 may fill a space between the upper surface 1000a of the semiconductor substrate 1000, the semiconductor chip 100, and the plurality of protective patterns 500.

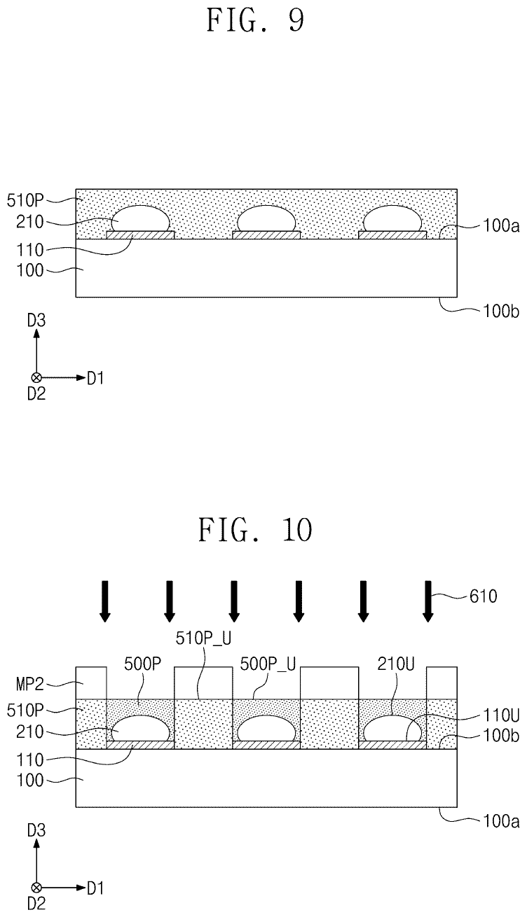

FIG. 9 to FIG. 14 are views showing a method for manufacturing a semiconductor package according to some embodiments of the inventive concept, and are cross-sectional views corresponding to A-A′ of FIG. 1. In order to simplify the description, the same descriptions as those of the method for manufacturing a semiconductor package described with reference to FIG. 1 and FIG. 8 will be omitted.

Referring to FIG. 9, a flux agent 510P may be applied on a first surface 100a of a semiconductor chip 100. The flux agent 510P may cover the first surface 100a of the semiconductor chip 100, and may conformally cover a plurality of second conductive pads 110 and a plurality of connecting bumps 210 on the first surface 100a of the semiconductor chip 100. The applying of the flux agent 510P on the first surface 100a of the semiconductor chip 100 may include, for example, a spin coating process.

Referring to FIG. 10, a plurality of preliminary protective patterns 500P may be formed. An upper surface 500P_U of the plurality of preliminary protective patterns 500P may be positioned at a higher level than an upper surface 210U of a plurality of connecting bumps 210. The plurality of preliminary protective patterns 500P may cover the plurality of second conductive pads 110 and the plurality of connecting bumps 210. The plurality of preliminary protective patterns 500P may cover side surfaces of the plurality of second conductive pads 110 and the plurality of connecting bumps 210.

The forming of the plurality of preliminary protective patterns 500P may include forming a second mask pattern MP2 on the flux agent 510P, wherein the second mask pattern MP2 exposes an upper surface 510P_U of the flux agent 510P corresponding to an upper surface 110U of each of the plurality of second conductive pads 110, and curing the flux agent 510P by irradiating the exposed upper surface 510P_U of the flux agent 510P with light energy or heat energy 610.

By the light energy or heat energy, a curing reaction by a photoinitiator may occur. A curing reaction of a first compound of the flux agent 510P may occur. The light energy may include, for example, light (e.g., ultraviolet light) having a wavelength of 10 nm to 600 nm.

According to some embodiments of the inventive concept, the plurality of preliminary protective patterns 500P, which are cured products of the flux agent 510P, may be formed on the plurality of second conductive pads 110 and the plurality of connecting bumps 210. Each of the plurality of preliminary protective patterns 500P may be in a solid state at room temperature.

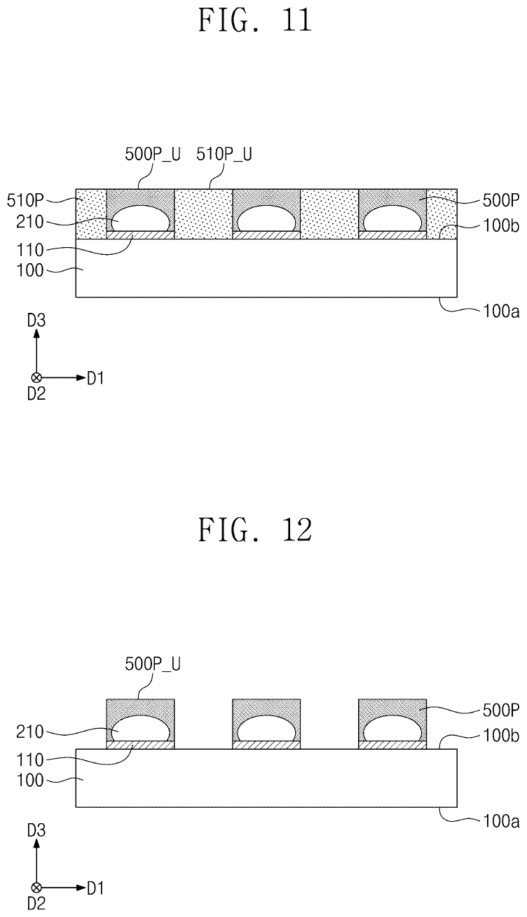

Referring to FIG. 11, the second mask pattern MP2 may be removed. An upper surface 500P_U of the plurality of preliminary protective patterns 500P and the upper surface 510P_U of the flux agent 510P may be exposed.

Referring to FIG. 12, the flux agent 510P may be removed. Accordingly, the first surface 100a of the semiconductor chip 100 may be exposed, and the side surfaces of the plurality of second conductive pads 110 and the plurality of preliminary protective patterns 500P may be exposed. The plurality of preliminary protective patterns 500P are in a solid state, and may not be removed. Also, a defect in which the plurality of preliminary protective patterns 500P flow or evaporate during a process of manufacturing a semiconductor package may not occur.

Furthermore, the semiconductor chip 100 on which the plurality of preliminary protective patterns 500P are formed may be stored for a long period of time. Application fixation of the flux agent 510P and a bonding process to be described later may be spatially and temporally dualized. A method for manufacturing various semiconductor packages may be applied.

In addition, prior to a bonding process of the semiconductor substrate 1000 and a semiconductor chip 100, the plurality of second conductive pads 210 and the plurality of connecting bumps 210 may be physically and chemically protected by the plurality of preliminary protective patterns 500P.

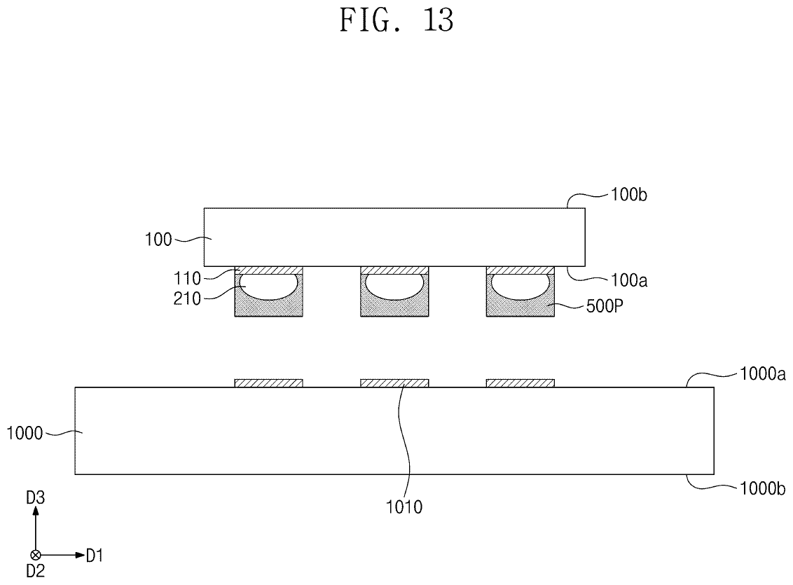

Referring to FIG. 13, a plurality of first conductive pads 1010 may be formed on an upper surface 1000a of a semiconductor substrate 1000. The first surface 100a of the semiconductor chip 100 may be provided to face the upper surface 1000a of the semiconductor substrate 1000. Each of the plurality of second conductive pads 110 and the plurality of connecting bumps 210 may be aligned on a corresponding first conductive pad among the plurality of first conductive pads 1010.

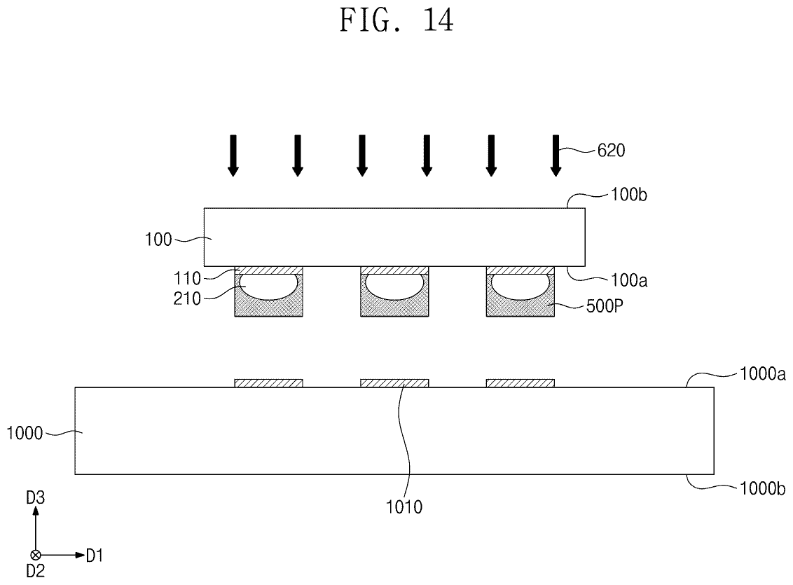

Referring to FIG. 14, a bonding process 620 may be performed. The bonding process 620 may include applying pressure to the semiconductor chip 100 and the semiconductor substrate 1000 which are aligned. The bonding process 620 may include applying pressure to the semiconductor chip 100 and the semiconductor substrate 1000, and applying light energy or heat energy to the plurality of preliminary protective patterns 500P.

The rest of the manufacturing method may be substantially the same as the manufacturing method of the semiconductor package described with reference to FIG. 1 and FIG. 8.

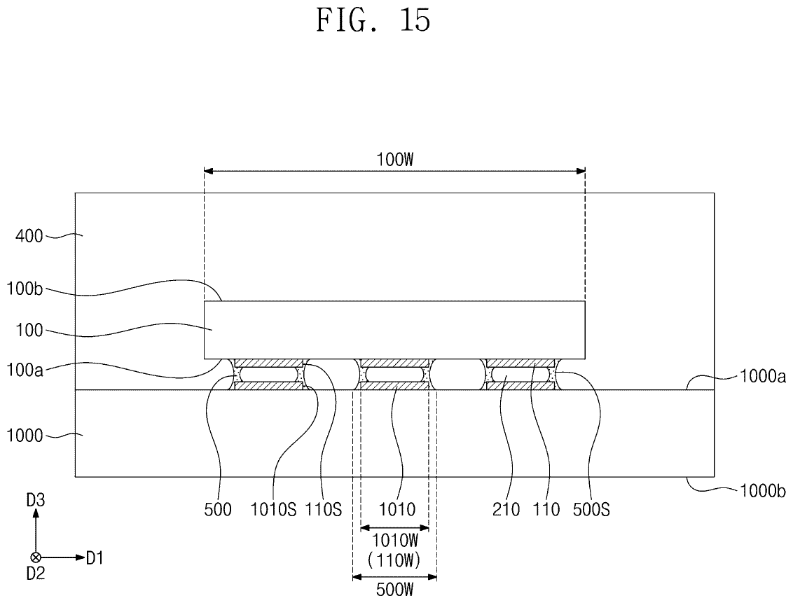

FIG. 15 is a cross-sectional view of a semiconductor package according to some embodiments of the inventive concept, and are cross-sectional views taken along A-A′ of FIG. 1. In order to simplify the description, the same descriptions as those of the semiconductor package described with reference to FIG. 1 and FIG. 2 will be omitted.

Referring to FIG. 1 and FIG. 15, a plurality of protective patterns 500 may be interposed between a semiconductor chip 100 and a semiconductor substrate 1000. The plurality of protective patterns 500 may come into contact with an upper surface 1000a of the semiconductor substrate 1000 and a first surface 100a of the semiconductor chip 100. The plurality of protective patterns 500 may be spaced apart from each other in a first direction D1 and a second direction D2.

The plurality of protective patterns 500 may cover a plurality of first and second conductive pads 1010 and 110 and a plurality of connecting bumps 210. More specifically, each of the plurality of protective patterns 500 may cover a side surface 1010S of a corresponding first conductive pad 1010 and a side surface 110S of a corresponding second conductive pad 110. Each of the plurality of protective patterns 500 may conformally cover corresponding first and second conductive pads 1010 and 110 and a corresponding connecting bump 210.

Each of the plurality of protective patterns 500 may form, for example, a closed curve when viewed in a plan view. The plurality of protective patterns 500 may protect the plurality of first and second conductive pads 1011 and 110, and the plurality of connecting bumps 210 from external impurities and impacts.

A width 500 W of each of the plurality of protective patterns 500 in the first direction D1 may be smaller than a width 100 W of the semiconductor chip 100 in the first direction D1. The width 500 W of each of the plurality of protective patterns 500 in the first direction D1 may be larger than a width 1010 W of each of the plurality of first conductive pads 1010 in the first direction D1. The width 500 W of each of the plurality of protective patterns 500 in the first direction D1 may be larger than a width 110 W of each of the plurality of second conductive pads 110 in the first direction D1.

The rest of the components may be substantially the same as those of the semiconductor package described with reference to FIG. 1 and FIG. 2.

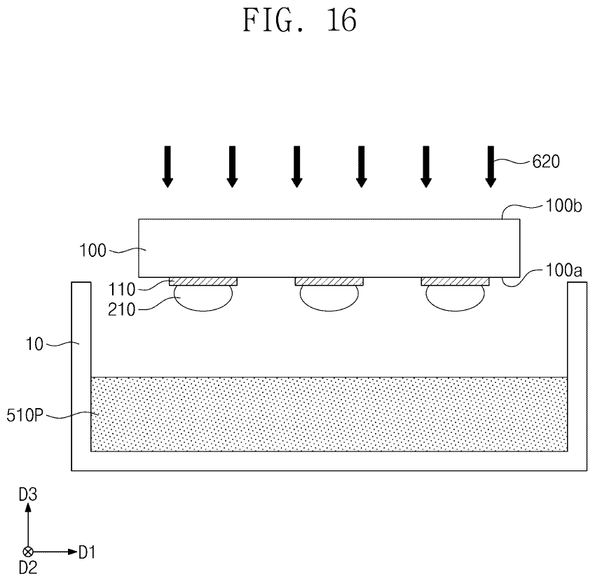

FIG. 16 to FIG. 19 are views showing a method for manufacturing a semiconductor package according to some embodiments of the inventive concept, and are cross-sectional views corresponding to A-A′ of FIG. 1. In order to simplify the description, the same descriptions as those of the method for manufacturing a semiconductor package described with reference to FIG. 1 and FIG. 8 will be omitted.

Referring to FIG. 16, a flux agent 510P may be prepared in a storage unit 10. The preparing of the flux agent 510P may include, for example, preparing a first compound, a fourth compound, a photoinitiator, and a solvent in the storage unit 10, and mixing the first compound, the fourth compound, the photoinitiator, and the solvent.

On the first surface 100a of the semiconductor chip 100, the plurality of second conductive pads 110 and the plurality of connecting bumps 210 on the plurality of second conductive pads 110 may be formed. On the plurality of second conductive pads 110 and the plurality of connecting bumps 210 on the first surface 100a of the semiconductor chip 100, the flux agent 510P may be formed.

The forming of the flux agent 510P on the first surface 100a of the semiconductor chip 100 may include, for example, impregnating the plurality of second conductive pads 110 and the plurality of connecting bumps 210 on the first surface 100a of the semiconductor chip 100 into the storage unit 10.

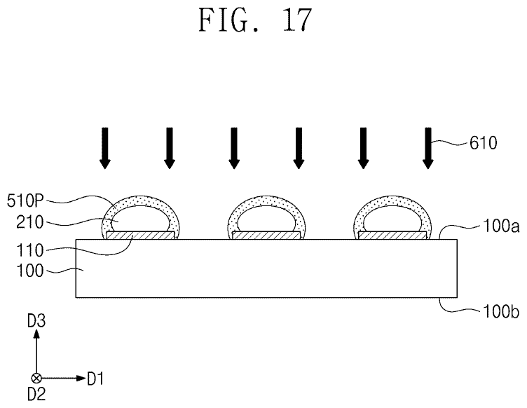

Referring to FIG. 17, a plurality of preliminary protective patterns 500P may be formed on the first surface 100a of the semiconductor chip 100. The plurality of preliminary protective patterns 500P may come into contact with the first surface 100a of the semiconductor chip 100, and may cover side surfaces of the plurality of second conductive pads 110. The plurality of preliminary protective patterns 500P may cover the plurality of connecting bumps 210.

The forming of the plurality of preliminary protective patterns 500P may include, for example, applying heat or light energy 610 to a flux agent on the first surface 100a of the semiconductor chip 100, thereby curing the flux agent. The light energy may include, for example, ultraviolet light having a wavelength of 10 nm to 600 nm.

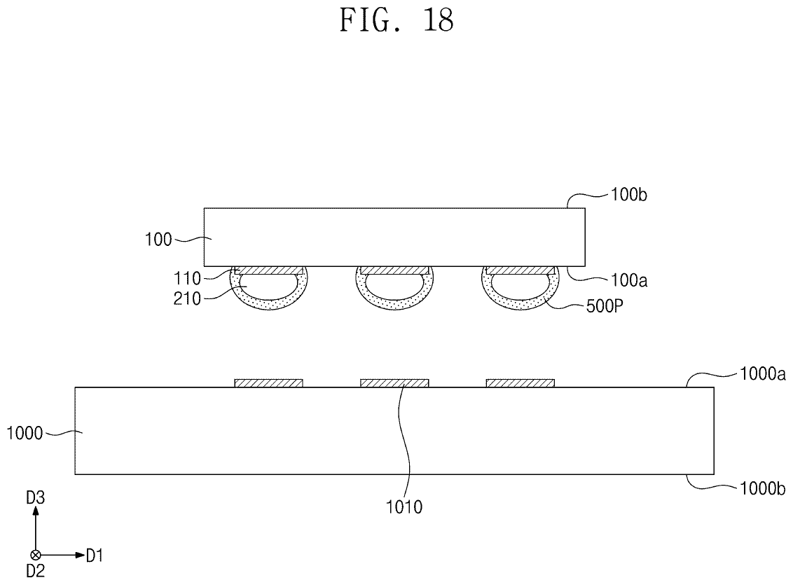

Referring to FIG. 18, a plurality of first conductive pads 1010 may be formed on an upper surface 1000a of a semiconductor substrate 1000. The first surface 100a of the semiconductor chip 100 may be provided to face the upper surface 1000a of the semiconductor substrate 1000. Each of the plurality of second conductive pads 110 and the plurality of connecting bumps 210 may be alignment to correspond to a corresponding first conductive pad 1010.

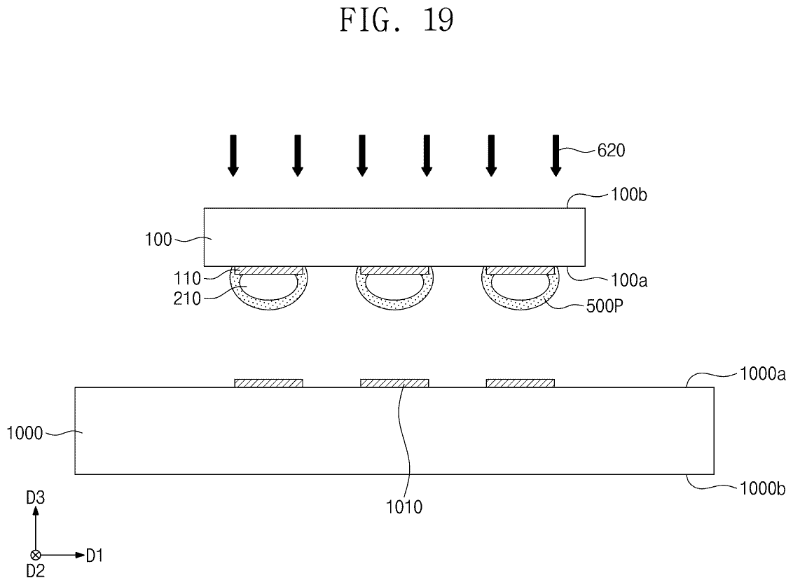

Referring to FIG. 19, a bonding process 620 may be performed. The bonding process 620 may include applying pressure to the semiconductor chip 100 and the semiconductor substrate 1000 which are aligned. The bonding process 620 may include applying pressure to the semiconductor chip 100 and the semiconductor substrate 1000, and applying light energy or heat energy to the plurality of preliminary protective patterns 500P.

According to some embodiments of the inventive concept, the plurality of preliminary protective patterns 500P, which are cured products of the flux agent, may be formed on the plurality of second conductive pads 110 and the plurality of connecting bumps 210. Each of the plurality of preliminary protective patterns 500P may be in a solid state at room temperature. Therefore, a defect in which the preliminary protective patterns 500P flow or evaporate during a process may not occur.

In addition, even if the first surface 100a of the semiconductor chip 100 is disposed to face the upper surface 1000a of the semiconductor substrate 1000, the plurality of preliminary protective patterns 500p may not flow. Therefore, the difficulty of a manufacturing process of a semiconductor package may be reduced. Furthermore, the semiconductor substrate 1000 on which the plurality

of preliminary protective patterns 500P are formed may be stored for a long period of time. Accordingly, application fixation of the flux agent and a bonding process to be described later may be spatially and temporally dualized. Accordingly, a method for manufacturing various semiconductor packages may be applied.

Referring back to FIG. 1 and FIG. 15, the plurality of protective patterns 500 may be formed. The forming of the plurality of protective patterns 500 may include, through the above-described bonding process, applying pressure to the plurality of preliminary protective patterns 500P, and applying heat or light energy to the plurality of preliminary protective patterns 500P. The light energy may include, for example, a laser having a wavelength of 600 nm to 3000 nm.

Due to the heat energy or light energy in the bonding process, the plurality of preliminary protective patterns 500P may have fluidity.

The plurality of preliminary protective patterns 500P may be pushed to side surfaces of the plurality of first and second conductive pads 1010 and 110 and the plurality of connecting bumps 210. The plurality of protective patterns 500 may cover side surfaces 1010S, 110S, and 500S of the plurality of first and second conductive pads 1010 and 110 and the plurality of connecting bumps 210, and may protect the plurality of first and second conductive pads 1010 and 110 and the plurality of connecting bumps 210.

Furthermore, due to the heat energy or light energy, a fourth compound in the plurality of preliminary protective patterns 500P may act as a reducing agent. Accordingly, a metal oxide on the plurality of connecting bumps 210 may be removed, and defects due to impurities during the bonding process may be removed.

The rest of the manufacturing method may be substantially the same as the manufacturing method of the semiconductor package described with reference to FIG. 1 and FIG. 8.

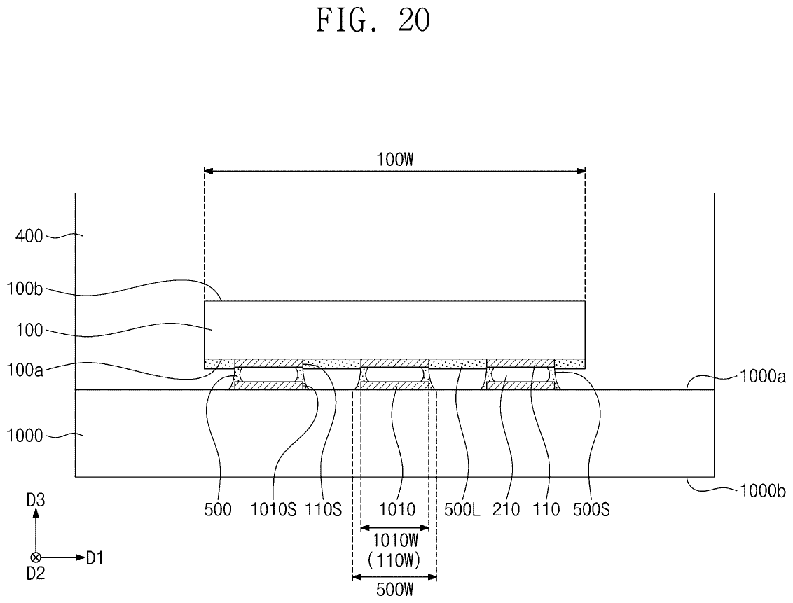

FIG. 20 is a cross-sectional view of a semiconductor package according to some embodiments of the inventive concept, and are cross-sectional views taken along A-A′ of FIG. 1. In order to simplify the description, the same descriptions as those of the semiconductor package described with reference to FIG. 1 and FIG. 2 will be omitted.

A protective layer 500L may be disposed on a first surface 100a of a semiconductor chip 100. The protective layer 500L may come into contact with the first surface 100a of the semiconductor chip 100, and may cover a side surface 110S of each of a plurality of second conductive pads 110.

Each of the plurality of protective patterns 500 may extend from the protective layer 500L toward an upper surface 1000a of a semiconductor substrate 1000. The protective layer 500L and the plurality of protective patterns 500 may be integrated with each other. The plurality of protective patterns 500 may be disposed between the semiconductor chip 100 and the semiconductor substrate 1000. The plurality of protective patterns 500 may come into contact with the upper surface 1000a of the semiconductor substrate 1000 and the first surface 100a of the semiconductor chip 100. The plurality of protective patterns 500 may be spaced apart from each other in a first direction D1 and a second direction D2.

The plurality of protective patterns 500 may cover a plurality of first and second conductive pads 1010 and 110 and a plurality of connecting bumps 210. More specifically, each of the plurality of protective patterns 500 may cover a side surface 1010S of a corresponding first conductive pad and a side surface 110S of a corresponding second conductive pad. The protective layer 500L and the plurality of protective patterns 500 may protect the plurality of first and second conductive pads, and the plurality of connecting bumps 210 from external impurities and impacts.

The protective layer 500L and the plurality of protective patterns 500 may be cured products of a flux agent. The flux agent may include a first compound including an ester group and an epoxy group, a fourth compound, and a photoinitiator. The content of the first compound may be 60 wt % to 95 wt % based on 100 wt % of the flux agent. If the content of the first compound satisfies the above-described numerical range, the formation of the protective pattern on the semiconductor chip 100, the semiconductor substrate 1000, the plurality of first and second conductive pads, and connecting bumps may effectively performed and after curing the protective pattern may allow sufficient fluidity during the bonding process

The first compound may include at least one of glycidyl epoxy and cyclohexene oxide. The content of fourth compound may be 3 wt % to 33 wt % based on 100 wt % of the flux agent. The fourth compound may be a chemical reactant of a second compound including an epoxy group and a third compound including an amine group and a carboxyl group. The fourth compound may include a covalent bond formed by the reaction between the epoxy group of the second compound and the amine group of the third compound. Furthermore, the fourth compound may include a covalent bond formed by the reaction between the epoxy group of the second compound and the carboxyl group of the third compound. That is, the fourth compound may not be a simple mixture of the second compound and the third compound.

If the content of the fourth compound satisfies the above-described numerical range, a metal oxide on the semiconductor chip 100, the semiconductor substrate 1000, and the plurality of first and second conductive pads may be effectively removed, and the formation of the protective pattern may be effectively performed. For example, if the content of the fourth compound is less than 3 wt % a metal oxide may not be removed effectively, the content of the fourth compound is greater than 33 wt % the protective pattern may not be formed effectively.

The content of the photoinitiator may be 2 wt % to 10 wt % based on 100 wt % of the flux agent. If the content of the photoinitiator is less than 2 wt %, a photo-curing reaction may not effectively occur. If the content of the photoinitiator is greater than 10 wt %, a metal oxide on the semiconductor chip 100 and the semiconductor substrate 1000 may not be effectively removed. The flux agent may further include a catalyst, a solvent, a leveling agent, and metal nanoparticles.

The rest of the components may be substantially the same as those of the semiconductor package described with reference to FIG. 1 and FIG. 2.

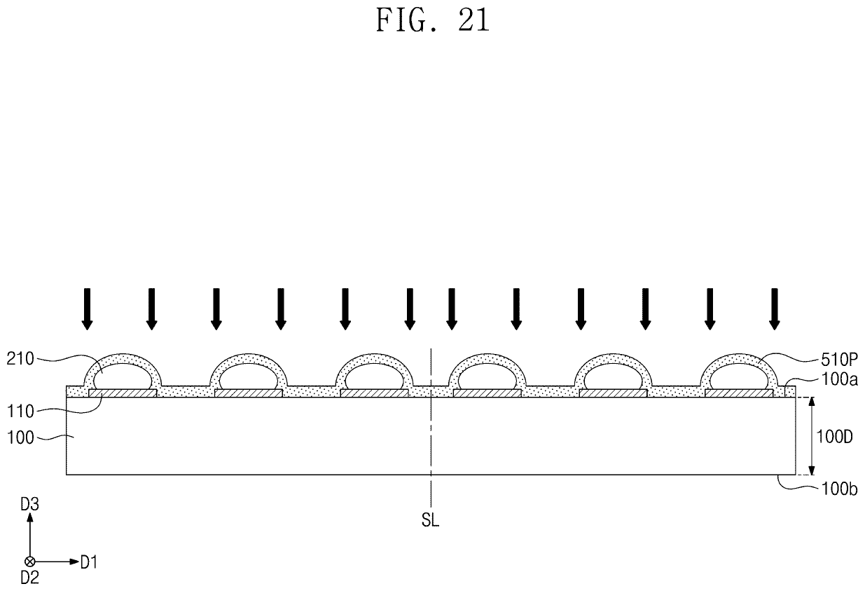

FIG. 21 to FIG. 25 are views showing a method for manufacturing a semiconductor package according to some embodiments of the inventive concept, and are cross-sectional views corresponding to A-A′ of FIG. 1. In order to simplify the description, the same descriptions as those of the method for manufacturing a semiconductor package described with reference to FIG. 1 and FIG. 8 will be omitted.

Referring to FIG. 21, a flux agent 510P may be formed on a first surface 100a of a semiconductor chip 100. The flux agent 510P may cover the first surface 100a of the semiconductor chip 100, and may cover all of a plurality of second conductive pads 110 and a plurality of connecting bumps 210 on the first surface 100a of the semiconductor chip 100. The forming of the flux agent 510P on the first surface 100a of the semiconductor chip 100 may include, for example, a spin coating process.

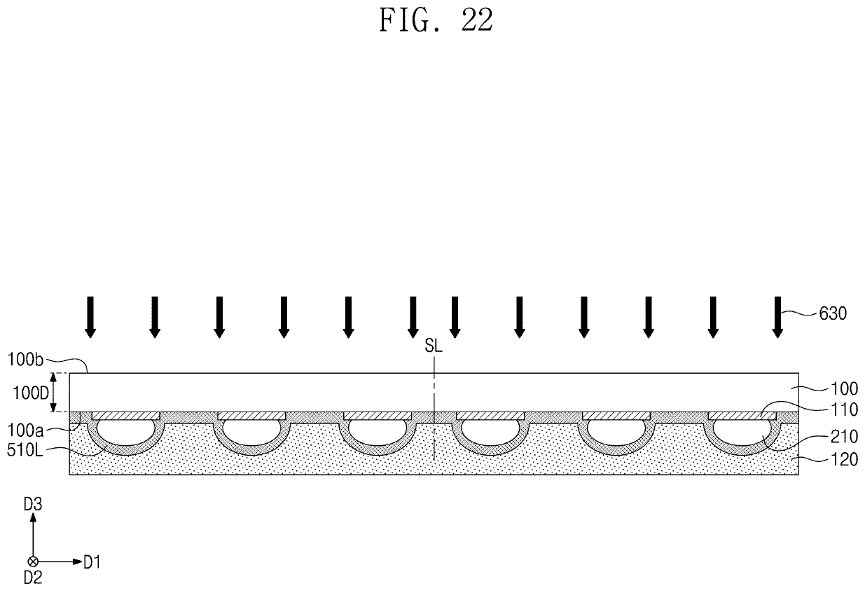

Referring to FIG. 22, a preliminary protective layer 510L may be formed. The preliminary protective layer 510L may cover the plurality of second conductive pads 110 and the plurality of connecting bumps 210. The forming of the preliminary protective layer 510L may include irradiating the flux agent 510P with light or heat energy, thereby curing the flux agent 510P.

By the light energy or heat energy, a curing reaction by a photoinitiator may occur. A curing reaction of a first compound of the flux agent 510P may occur. Accordingly, the flux agent 510P may be cured. The light energy may include, for example, light (e.g., ultraviolet light) having a wavelength of 10 nm to 600 nm.

A temporary tape 120 may be formed on the first surface 100a of the semiconductor chip 100. The temporary tape 120 may be formed on the preliminary protective layer 510L, and may conformally cover the preliminary protective layer 510L.

A back-grinding process 630 may be performed on a second surface 100b of the semiconductor chip 100. Due to the back-grinding process 630, a thickness 100D of the semiconductor chip 100 in a third direction D 3 may decrease. Accordingly, the degree of integration of the semiconductor package may be improved. Due to the preliminary protective layer 510L, the first surface 100a of the semiconductor chip 100, the plurality of second conductive pads 110, and the plurality of connecting bumps 210 may be prevented from having an oxide formed thereon, and may be physically and chemically protected.

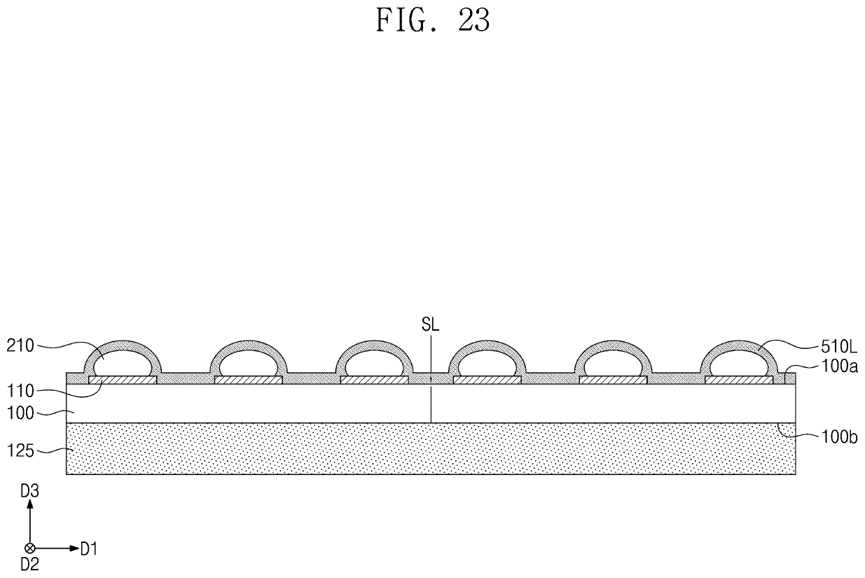

Referring to FIG. 23, a protective tape 125 may be disposed on the second surface 100b of the semiconductor chip 100. The protective tape 125 may conformally cover the second surface 100b of the semiconductor chip 100. The protective tape 125 may come into contact with the second surface 100b of the semiconductor chip 100. Through the protective tape 125, the semiconductor chip 100 may be protected from a physical impact. The temporary tape 120 on the first surface 100a of the semiconductor chip 100 may be removed.

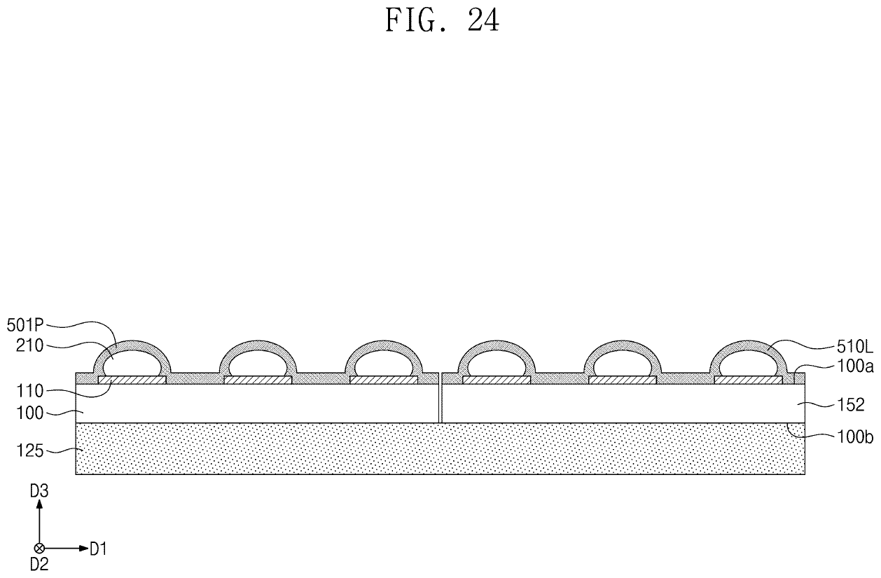

Referring to FIG. 24, a dicing process of sawing along a sawing line SL between the semiconductor chips 100 may be performed. Individually separated semiconductor chips 100 may be formed.

An additional cleaning process may be further included to remove foreign substances generated by the dicing process. Through the preliminary protective layer 510L, the first surface 100a of the during the semiconductor chip 100, the plurality of second conductive pads 110, and the plurality of connecting bumps 210 may be prevented from having an oxide formed thereon during the cleaning process, and may be physically and chemically protected.

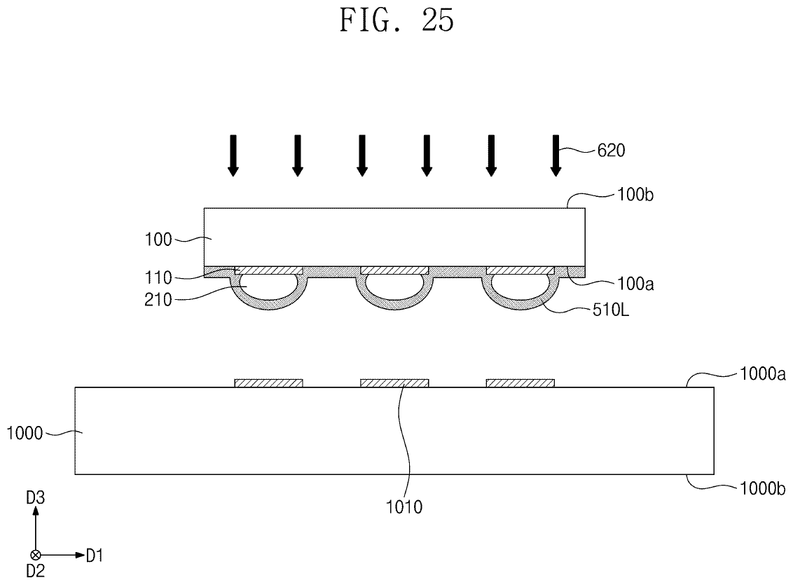

Referring to FIG. 25, a plurality of first conductive pads 1010 may be formed on an upper surface 1000a of a semiconductor substrate 1000. The first surface 100a of the semiconductor chip 100 may be provided to face the upper surface 1000a of the semiconductor substrate 1000. Each of the plurality of second conductive pads 110 and the plurality of connecting bumps 210 may be alignment to correspond to a corresponding first conductive pad 1010.

A bonding process 620 may be performed. The bonding process 620 may include applying pressure to the semiconductor chip 100 and the semiconductor substrate 1000 which are aligned. The bonding process 620 may include applying pressure to the semiconductor chip 100 and the semiconductor substrate 1000, and applying light energy or heat energy to the plurality of preliminary protective patterns 500P.

Referring back to FIG. 1 and FIG. 20, a protective layer 500L and a plurality of protective patterns 500 may be formed. The forming of the protective layer 500L and the plurality of protective patterns 500 may include, through above-described bonding process, applying pressure to the preliminary protective layer 510L, and applying heat or light energy to the preliminary protective layer 510L. The light energy may include, for example, a laser having a wavelength of 600 nm to 3000 nm.

Due to the heat energy or light energy in the bonding process, the preliminary protective layer 510L may have fluidity. A portion of the preliminary protective layer 510L may be pushed to side surfaces of the plurality of first and second conductive pads 1010 and 110 and the plurality of connecting bumps 210. The portion of the preliminary protective layer 510L may cover side surfaces 1010S, 110S, and 500S of the plurality of first and second conductive pads 1010 and 110 and the plurality of connecting bumps 210. The portion of the preliminary protective layer 510L may come into contact with the upper surface 1000a of the semiconductor substrate 1000. The portion of the preliminary protective layer 510L may form the plurality of protective patterns 500.

Furthermore, due to the heat energy or light energy, a fourth compound in the preliminary protective layer 510L may be activated. Accordingly, a metal oxide on the plurality of connecting bumps 210 may be removed.

The rest of the manufacturing method may be substantially the same as the manufacturing method of the semiconductor package described with reference to FIG. 1 and FIG. 8.

FIG. 26 is a cross-sectional view according to some embodiments of the inventive concept, and is a cross-sectional view taken along line A-A′ of FIG. 1. In order to simplify the description, the same descriptions as those of the semiconductor package described with reference to FIG. 1 and FIG. 2 will be omitted.

Referring to FIG. 1 and FIG. 26, a buffer chip 1200 including an upper surface 1200a and a lower surface 1200b which are opposite to each other may be provided. The buffer chip 1200 may include, for example, an interposer or a logic circuit chip.

A plurality of first conductive pads 1010 may be disposed on an upper surface 1200a of the buffer chip 1200. The plurality of first conductive pads may be spaced apart from each other in a first direction D1 and a second direction. A lower external pad 1210 and a lower external connecting terminal 1220 on the lower external pad 1210 may be disposed on a lower surface 1200b of the buffer chip 1200.

A plurality of semiconductor chips MC may be disposed on the buffer chip 1200. The plurality of semiconductor chips MC may include, for example, a first semiconductor chip S1, a second semiconductor chip S2, and a third semiconductor chip S3. The first and second semiconductor chips S1 and S2 may include, for example, any one of DRAM, NAND flash, SRAM, MRAM, PRAM, and RRAM. The third semiconductor chip S3 may be, for example, a dummy chip.

The first semiconductor chip S1 may be a semiconductor chip closest to the buffer chip 1200, and the third semiconductor chip S3 may be a semiconductor chip farthest from the buffer chip 1200. The second semiconductor chip S2 may be a semiconductor chip interposed between the first semiconductor chip S1 and the third semiconductor chip S3. The number of the second semiconductor chips S2 is not limited to what is shown in FIG. 26. The number of the second semiconductor chips S2 may be plural.

The first semiconductor chip S1 may be connected to the buffer chip 1200 through a plurality of first connecting bumps 211. More specifically, the plurality of first connecting bumps 211 may be interposed between the plurality of first conductive pads 1010 of the buffer chip 1200 and a plurality of second conductive pads 110 on a first surface 100a of the first semiconductor chip. Accordingly, the first semiconductor chip S1 may be electrically connected to the buffer chip 1200. The plurality of first connecting bumps 211 may be, for example, solder.

A plurality of first protective patterns 501 may be interposed between the first semiconductor chip S1 and the buffer chip 1200. The plurality of first protective patterns 501 may cover the plurality of first connecting bumps 211. The plurality of first protective patterns 501 may correspond to the plurality of protective patterns 500 described with reference to FIG. 1 and FIG. 2.

Each of the first to third semiconductor chips S1, S2, and S3 may include substantially the same configuration as each other. Each of the first to third semiconductor chips S1, S2, and S3 may include a first surface 100a and a second surface 100b which are opposite to each other. Each of the first to third semiconductor chips S1, S2, and S3 may include a plurality of second conductive pads 110 on the first surface 100a, and may include a plurality of third conductive pads 111 on the second surface 100b. The plurality of third conductive pads 111 on the second surface 100b of the third semiconductor chip S3 may be omitted.

Each of the first and second semiconductor chips S1 and S2 may include a circuit layer 101 on the first surface 100a, a semiconductor layer 102 on the circuit layer 101, and a passivation layer 103 on the semiconductor layer 102. Each of the first and second semiconductor chips S1 and S2 may include a through-via 100V passing through the inside of the first and second semiconductor chips S1 and S2. The third semiconductor chip S3 may not include a circuit layer, a semiconductor layer, and a through-via. Due to the formation of the dummy chip, defects in a process may be reduced, and a heat management system may be improved.

The first to third semiconductor chips S1, S2, and S3 may be electrically connected to each other through a plurality of second connecting bumps 212. More specifically, the plurality of second connecting bumps 212 may be disposed between the second surface 100b of the first semiconductor chip S1 and the first surface 100a of the second semiconductor chip S2. The plurality of second connecting bumps 212 may be disposed between the second surface 100b of the second semiconductor chip S2 and the first surface 100a of the third semiconductor chip S3. The plurality of second connecting bumps 212 may be disposed between the plurality of second conductive pads 110 and the plurality of third conductive pads 111. Accordingly, the first to third semiconductor chips S1, S2, and S3 may be electrically connected to each other. The plurality of second connecting bumps 212 may be, for example, solder.

A plurality of second protective patterns 502 may be interposed between the first to third semiconductor chips S1, S2, and S3. Each of the plurality of second protective patterns 502 may come into contact with the first surface 100a and the second surface 100b of each of the first to third semiconductor chips S1, S2, and S3. The plurality of second protective patterns 502 may cover the plurality of second and third conductive pads 110 and 111. The plurality of second protective patterns 502 may cover the plurality of second connecting bumps 212. The plurality of first protective patterns 502 may correspond to the plurality of protective patterns 500 described with reference to FIG. 2 and FIG. 2.

A molding film 400 may be disposed on the upper surface 1200a of the buffer chip 1200. The molding film 400 may cover a plurality of semiconductor chips MC, and may fill a space between the plurality of second protective patterns 502. The molding film 400 may come into contact with the first surface 100a and the second surface 100b of each of the first to third semiconductor chips S1, S2, and S3. The molding film 400 may comprise, for example, an epoxy molding compound, a molded underfill.

The rest of the components may be substantially the same as those of the semiconductor package described with reference to FIG. 1 and FIG. 2.

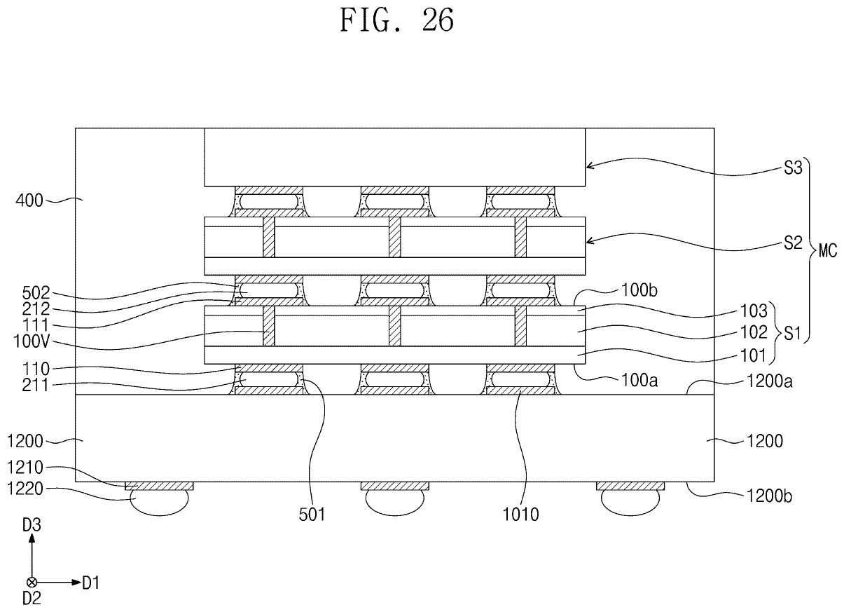

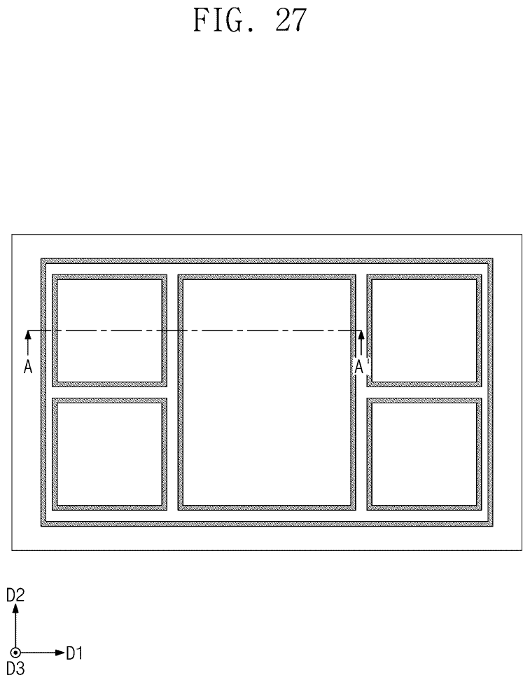

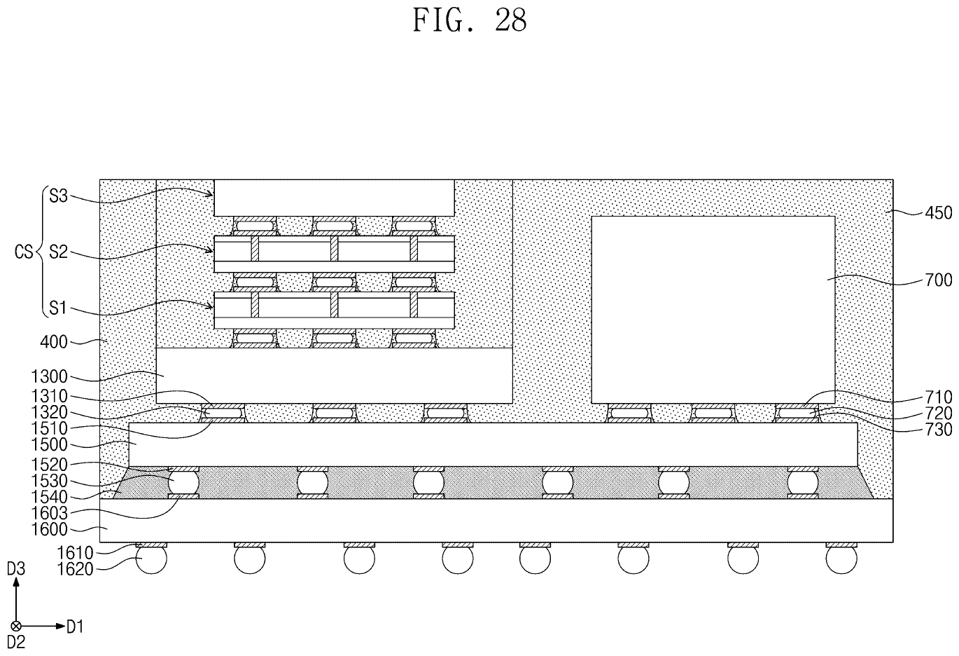

FIG. 27 is a plan view of a semiconductor package according to some embodiments of the inventive concept. FIG. 28 is a cross-sectional view of a semiconductor package according to some embodiments of the inventive concept, and is a cross-sectional view taken along A-A′ of FIG. 27. In order to simplify the description, the same descriptions as those of the semiconductor package described with reference to FIG. 1 and FIG. 2 will be omitted.

Referring to FIG. 27 and FIG. 28, a package substrate 1600, an interposer substrate 1500 on the package substrate 1600, a first semiconductor substrate 1300 on the interposer substrate 1500, a graphics processing unit 700 on the interposer substrate 1500, and a chip stack CS on the first semiconductor substrate 1300 may be included.

The package substrate 1600 may be, for example, any one of a printed circuit board, a semiconductor chip, and a semiconductor package. The package substrate 1600 may include upper pads 1603 on an upper surface thereof. The package substrate 1600 may include lower pads 1610 on a lower surface thereof. The lower pads 1610 may be electrically connected to the upper pads 1603 through internal wirings disposed inside the package substrate 1600. The package substrate 1600 may include lower bumps 1620 on the lower surface thereof, and each of the lower bumps 1620 may be disposed on a corresponding lower pad among the lower pads 1610.

The interposer substrate 1500 may rewire the first semiconductor substrate 1300 and the graphics processing unit 700. The interposer substrate 1500 may be mounted on the package substrate 1600 in a flip-chip manner.

The interposer substrate 1500 may include first connecting pads 1520 on a lower surface thereof. The interposer substrate 1500 may include first bumps 1530 on the lower surface thereof. Each of the first bumps 1530 may be electrically connected to a corresponding first connecting pad among the first connecting pads 1520. A first underfill 1540 may be disposed between the interposer substrate 1500 and the package substrate 1600. The first underfill 1540 may cover the first bumps 1530.

Second connecting pads 1510 may be disposed on an upper surface of the interposer substrate 1500. The second connecting pads 1510 may be electrically connected to the first connecting pads 1520 through internal wirings disposed inside the interposer substrate 1500.

The first semiconductor substrate 1300 may be connected to the interposer substrate 1500 through external terminals 1310. The external terminals 1310 may be electrically connected to the second connecting pads 1510 of the interposer substrate 1500. The first semiconductor substrate 1300 may correspond to the buffer chip 1200 described with reference to FIG. 26. The chip stack CS may be disposed on the first semiconductor substrate 1300. The chip stack CS may correspond to the plurality of semiconductor chips MC described with reference to FIG. 26. A molding film 400 may cover the first semiconductor substrate 1300 and the chip stack CS. The molding film 400 may correspond to the molding film described with reference to FIG. 26.

The graphics processing unit 700 may be disposed on the interposer substrate 1500. The graphics processing unit 700 may be spaced apart from the first semiconductor substrate 1300 in the first direction D1. A thickness of the graphics processing unit 700 may be greater than a thickness of each of semiconductor chips of the chip stack CS. The graphics processing unit GPU 700 may be, for example, a logic chip. Pads 710 and bumps 720 on the pads 710 may be disposed on a lower surface of the graphics processing unit 700. The graphics processing unit 700 may be electrically connected to the interposer substrate 1500 through the bumps 720. Lower protective patterns 730 may cover the pads 710 and the bumps 720. The configuration of the lower protective pattern 730 may correspond to that of the plurality of protective patterns described with reference to FIG. 1 and FIG. 2.

An outer molding film 450 may be disposed on the package substrate 1600. The outer molding film 450 may cover the interposer substrate 1500, the first semiconductor substrate 1300, the chip stack CS, and the graphics processing unit 700. The outer molding film may comprise, for example, an epoxy molding compound, a molded underfill.

The rest of the components may be substantially the same as those of the semiconductor package described with reference to FIG. 1 and FIG. 2.

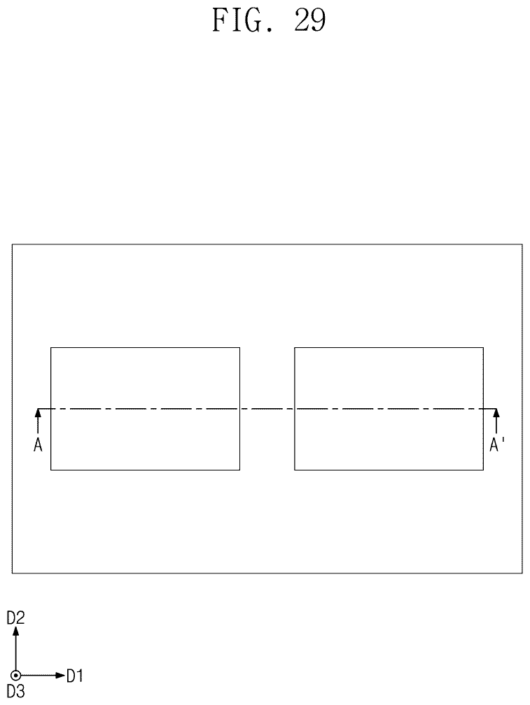

FIG. 29 is a plan view of a semiconductor package according to some embodiments of the inventive concept. FIG. 30 is a cross-sectional view of a semiconductor package according to some embodiments of the inventive concept, and is a cross-sectional view taken along A-A′ of FIG. 29. In order to simplify the description, the same descriptions as those of the semiconductor package described with reference to FIG. 1 and FIG. 2 will be omitted.

Referring to FIG. 29 and FIG. 30, a plurality of first conductive pads 1010 may be disposed on an upper surface 1000a of a semiconductor substrate 1000. A first semiconductor die 151 and a second semiconductor die 152 may be disposed on the upper surface 1000a of the semiconductor substrate 1000.

The first semiconductor die 151 may include, for example, a logic chip. The second semiconductor die 152 may include, for example, a memory chip, and may include, for example, a volatile memory semiconductor chip such as dynamic random access memory (DRAM) or static random access memory (SRAM). The second semiconductor die 152 may include, for example, a non-volatile memory semiconductor chip such as a flash memory, a phase-change random access memory (PRAM), a magnetic random access memory (MRAM), a ferroelectric random access memory (FeRAM), or a resistive random access memory (RRAM). However, the inventive concept is not limited thereto, and the first semiconductor die 151 may include a memory chip.

The first semiconductor die 151 may include a third surface 151a and a fourth surface 151b which are opposite to each other. The third surface 151a of the first semiconductor die 151 may face the upper surface 1000a of the semiconductor substrate 1000. A plurality of second conductive pads 110 may be disposed on the third surface 151a of the first semiconductor die 151. The plurality of second conductive pads 110 may be disposed to correspond to the plurality of first conductive pads 1010.

The second semiconductor die 152 may include a fifth surface 152a and a sixth surface 152b which are opposite to each other. The fifth surface 152a of the second semiconductor die 152 may face the upper surface 1000a of the semiconductor substrate 1000. A plurality of third conductive pads 121 may be disposed on the fifth surface 152a of the second semiconductor die 152. The plurality of third conductive pads 121 may be disposed to correspond to the plurality of first conductive pads 1010.

A plurality of connecting bumps 210 may be disposed between the plurality of first conductive pads 1010 and the plurality of second conductive pads 110 and between the plurality of first conductive pads 1010 and the plurality of third conductive pads 121. Accordingly, the first semiconductor die 151 and the semiconductor substrate 1000 may be electrically connected to each other, and the second semiconductor die 152 and the semiconductor substrate 1000 may be electrically connected to each other. The plurality of connecting bumps 210 may be solder.

A plurality of protective patterns 500 may be disposed between the first semiconductor die 151 and the semiconductor substrate 1000 and between the second semiconductor die 152 and the semiconductor substrate 1000. Each of the plurality of protective patterns 500 may come into contact with the third surface 151a of the first semiconductor die 151, and may come into contact with the fifth surface 152a of the second semiconductor die 152. Each of the plurality of protective patterns 500 may come into contact with the upper surface 1000a of the semiconductor substrate 1000.

Each of the plurality of protective patterns 500 may cover corresponding first and second conductive pads among the plurality of first and second conductive pads 1010 and 110. Each of the plurality of protective patterns 500 may cover corresponding first and third conductive pads among the plurality of first and third conductive pads 1010 and 121. Each of the plurality of protective patterns 500 may cover a corresponding connecting bump among the plurality of connecting bumps 210. The plurality of protective patterns 500 may correspond to the plurality of protective patterns 500 described with reference to FIG. 1 and FIG. 2.

A molding film 400 may be disposed on the upper surface 1000a of the semiconductor substrate 1000. The molding film 400 may cover the first and second dies 151 and 152, and may fill a space between the plurality of protective patterns 500. The molding film 400 may come into contact with the upper surface 1000a of the semiconductor substrate 1000, and may come into contact with the third surface 151a of the first semiconductor die 151 and the fifth surface 152a of the second semiconductor die 152.

The molding film 400 may come into contact with a side surface 500S of the plurality of protective patterns 500. The molding film 400 may include, for example, an epoxy molding compound. The molding film 400 may protect the semiconductor package from impurities, and external impacts.

The rest of the components may be substantially the same as those of the semiconductor package described with reference to FIG. 1 and FIG. 2.

Hereinafter, the inventive concept will be described with reference to the following example.

### Example

3,4-Epoxycyclohexylmethyl 3,4-epoxycyclohexanecarboxylate was prepared as a first compound. 3-Glycidoxypropyltrimethoxysilane was prepared as a second compound. L-Lysine was prepared as a third compound. 12.5 g of the second compound and 5.2 g of the third compound were reacted in flask at 181° C. for 5 hours to form the fourth compound. triarylsulfonium hexafluorophosphate salt was prepared as a photoinitiator. 1,5,7-triazabicyclo[4.4.0]dec-5-ene was prepared as a catalyst. Tin was prepared from metal nanoparticles, and the average particle diameter of the metal nanoparticles was 0.1 μm. The first compound, the fourth compound, the photoinitiator, the catalyst, and the metal nanoparticles were mixed in acetone to form a flux agent. In this case, the content of the first compound was 81 wt % based on 100 wt % of the flux agent solid, and the content of the fourth compound was 13 wt % based on 100 wt % of the flux agent solid. The content of the photoinitiator was 4 wt % based on 100 wt % of flux agent solid.

### Evaluation Example: Scanning Electron Microscope (SEM) Photograph

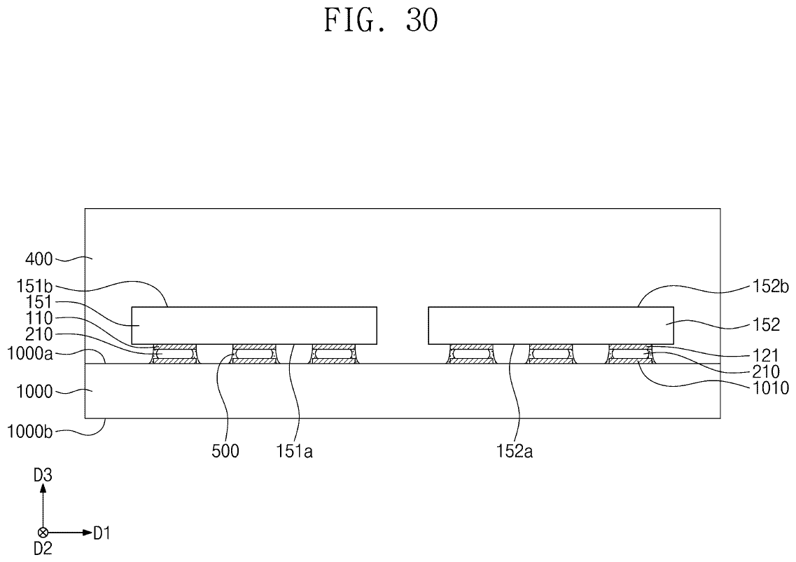

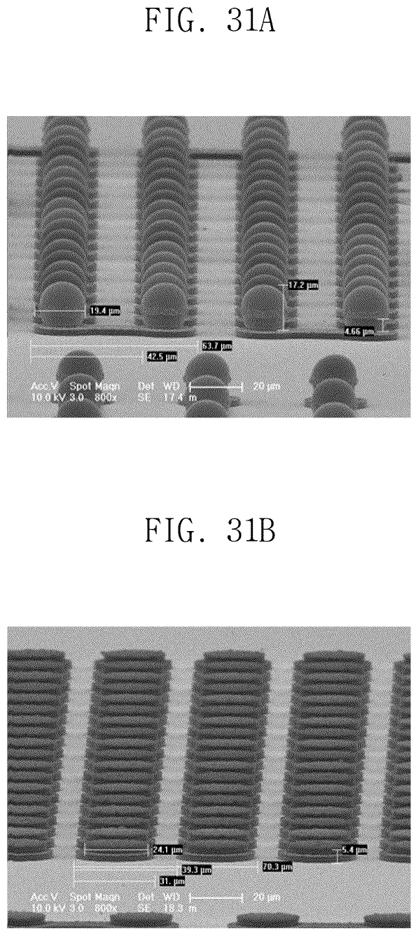

FIG. 31A is a result of photographing a semiconductor chip using a scanning electron microscope. FIG. 31B is a result of photographing a semiconductor substrate using a scanning electron microscope.

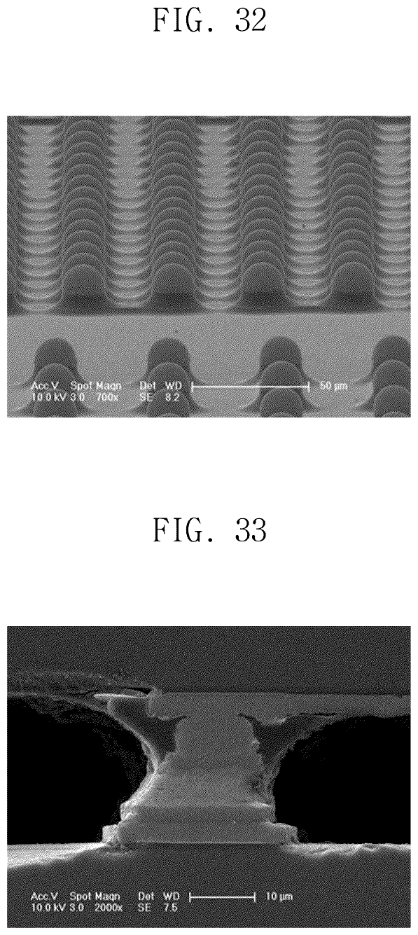

FIG. 32 is a result of photographing a protective pattern according to the embodiment formed on the semiconductor chip according to FIG. 31A. The flux agent according to the embodiment was applied on the semiconductor chip and then cured by being applied with light energy to form a protective pattern. The light energy was ultraviolet light having a wavelength of 365 nm. Thereafter, an image was photographed through a scanning electron microscope.

FIG. 33 is result of photographing a cross-section of a junction after performing a bonding process on the semiconductor chip having a protection pattern formed in FIG. 32 to the semiconductor substrate of FIG. 31B. The bonding process was performed by applying a pressure of about 1.5N to the semiconductor chip and the semiconductor substrate while applying heat by irradiating the semiconductor chip with a laser having 980 nm wavelength.

Referring to FIG. 32 and FIG. 33, it can be seen that the flux agent was cured, so that the protective pattern was formed. Furthermore, it can be confirmed that the protective pattern was formed in a solid state.

### Evaluation Example: Evaluation of Electrical Resistance

The electrical resistance of the solder bump formed between the semiconductor chip and the semiconductor substrate bonded by the bonding process of FIG. 32 and FIG. 33 was measured three times.

TABLE 1

| | Electrical resistance (mΩ) |
|---|---|
| 1 time | 4.7 |
| 2 times | 4.7 |
| 3 times | 4.79 |
| Average value | 4.73 |

Referring to Table 1, it can be confirmed that the electrical resistance of the solder bump is as low as about 4.73 mΩ. Therefore, it can be confirmed that the flux agent according to the embodiment and the protective pattern, which is a cured product thereof, may implement both the flux function and the underfill function.

According to embodiments of the inventive concept, a protective pattern may be a cured product of a flux agent. Accordingly, the protective pattern may perform both a flux function of removing a metal oxide from a semiconductor chip, a semiconductor package, a conductive pad, and connecting bumps, and an underfill function of protecting the same.

Furthermore, the protective pattern may be in a solid state at room temperature as a cured product of the flux agent. A bonding portion may be physically and chemically protected through the protective pattern before a bonding process of a semiconductor substrate and a semiconductor chip. In addition, in the bonding process, a risk in which the protective pattern flows may be eliminated. Accordingly, the difficulty of a manufacturing process of a semiconductor package may be reduced.

Furthermore, after the formation of the protective pattern, the semiconductor chip and the semiconductor substrate may be stored for a long period of time. Accordingly, application fixation and the bonding process of the flux agent may be spatially and temporally dualized. Accordingly, a method for manufacturing various semiconductor packages may be applied.

Although the embodiments of the inventive concept have been described with reference to the accompanying drawings, those skilled in the art will appreciate that the present invention can be variously modified and changed without departing from the spirit and scope of the present invention as set forth in the following patent claims. In addition, the embodiments disclosed herein are not intended to limit the technical spirit of the present invention, and all technical concepts falling within the scope of the following claims and equivalents thereof are to be construed as being included in the scope of the inventive concept.

What is claimed is:

1. A flux agent comprising:
a first compound comprising an ester group and an epoxy group;
a fourth compound which is a chemical reactant of a second compound comprising an epoxy group and a third compound comprising an amine group and a carboxyl group; and
a photoinitiator,
wherein:
the content of the first compound is 60 wt % to 95 wt % based on 100 wt % of the total agent;
the content of the fourth compound is 3 wt % to 33 wt % based on 100 wt % of the total agent; and
the content of the photoinitiator is 2 wt % to 10 wt % based on 100 wt % of the total agent.

2. The flux agent of claim 1, wherein the first compound and the second compound each comprise at least one of glycidyl epoxy or cyclohexene oxide.

3. The flux agent of claim 1, wherein the first compound comprises one or more selected from the group consisting of Methyl 3-(7-oxabicyclo[4.1.0]heptan-3-yl)-7-oxabicyclo[4.1.0]heptane-3-carboxylate, (5-Methyl-7-oxabicyclo[4.1.0]heptan-3-yl)methyl 5-methyl-7-oxabicyclo[4.1.0]heptane-3-carboxylate, [2,2-Dimethyl-3-(6-methyl-7-oxabicyclo[4.1.0]heptane-3-carbonyl)oxypropyl] 6-methyl-7-oxabicyclo[4.1.0]heptane-3-carboxylate, (1-Methyl-7-oxabicyclo[4.1.0]heptan-3-yl)methyl 1-methyl-7-oxabicyclo[4.1.0]heptane-3-carboxylate, 7-Oxabicyclo[4.1.0]heptan-2-ylmethyl 7-oxabicyclo[4.1.0]heptane-3-carboxylate, 6-(7-Oxabicyclo[4.1.0]heptan-1-ylmethyl)-7-oxabicyclo[4.1.0]heptane-3-carboxylate, (2-Methyl-7-oxabicyclo[4.1.0]heptan-3-yl)methyl 2-methyl-7-oxabicyclo[4.1.0]heptane-3-carboxylate, 2-(7-Oxabicyclo[4.1.0]heptan-3-yl) ethyl 7-oxabicyclo[4.1.0]heptane-3-carboxylate, 2-[2-(7-Oxabicyclo[4.1.0]heptane-3-carbonyloxy)ethoxy]ethyl 7-oxabicyclo[4.1.0]heptane-3-carboxylate, Bis(7-oxabicyclo[4.1.0]heptan-3-ylmethyl) heptanedioate, 3,4-Epoxycyclohexylmethyl 3,4-epoxycyclohexanecarboxylate, Bis(3,4-epoxycyclohexylmethyl) adipate, Chissonox 201, 3-[2-(3-Carboxylato-7-oxabicyclo[4.1.0]heptan-3-yl)ethyl]-7-oxabicyclo[4.1.0]heptane-3-carboxylate, 2-(7-Oxabicyclo[4.1.0]heptane-3-carbonyloxy) ethyl 7-oxabicyclo[4.1.0]heptane-3-carboxylate, 3,4-Epoxycyclohexyl-3,4-epoxycyclo-hexane carboxylate, 5-Methyl-3-[(5-methyl-7-oxabicyclo[4.1.0]heptan-3-yl)methyl]-7-oxabicyclo[4.1.0]heptane-3-carboxylate, 1,4-Cyclohexanedimethanol bis(3,4-epoxycyclohexanecarboxylate), Cyclohexylmethyl-3,4-epoxycyclohexanecarboxylate, Glycidyl methacrylate, Ethyl 2,3-epoxybutyrate, Methyl 3,4-epoxybutyrate, Ethyl oxirane-2-carboxylate, Glycidyl butyrate, (2-Methyloxiranyl)methyl methacrylate, 9,10-Epoxystearate, Diglycidyl isophthalate, oxiran-2-ylmethyl benzoate, Tris(oxiranylmethyl)benzene-1,3,5-tricarboxylate, Bis(2,3-epoxypropyl) terephthalate, Bis(oxiran-2-ylmethyl) 5-carbonochloridoylbenzene-1,3-dicarboxylate, and a combination thereof.

4. The flux agent of claim 1, wherein the third compound comprises one or more selected from the group consisting of alpha (α)-amino acid, beta (β)-amino acid, gamma (γ)-amino acid, delta (δ)-amino acid, anthranilic acid, 3-aminobenzoic acid, para-aminobenzoic acid, and a combination thereof.

5. The flux agent of claim 1, wherein the photoinitiator comprises one or more selected from the group consisting of 3-methyl-2-butenyltetramethylenesulfonium hexafluoroantimonate salt, ytterbium trifluoromethanesulfonate salt, samarium trifluoromethanesulfonate salt, erbium trifluoromethanesulfonate salt, triarylsulfonium hexafluoroantimonate salt, triarylsulfonium hexafluorophosphate salt, lanthanum trifluoromethanesulfonate salt, tetrabutylphosphonium methensulfonate salt, ethyltriphenylphosphonium bromide salt, diphenyldiodonium hexafluoroantimonate salt, diphenyldiodonium hexafluorophosphate salt, dithoriliodonium hexafluorophosphate salt, 9-(4-hydroxyethoxyphenyl)cyanthrhenium hexafluorophosphate salt, 1-(3-methylbut-2-enyl) tetrahydro-1H-thiophenium hexafluoroantimonate salt, 2-(9-oxoxanthen-2-yl) propionic acid 1,5,7-triazabicyclo[4.4.0]dec-5-ene salt, and a combination thereof.

6. The flux agent of claim 1, further comprising metal nanoparticles, wherein the metal nanoparticles contain one or more selected from the group consisting of tin, copper, silver, bismuth, indium, lead, cadmium, antimony, gallium, arsenic, germanium, zinc, aluminum, gold, silicon, nickel, phosphorus, and an alloy thereof.

7. The flux agent of claim 6, wherein the metal nanoparticles have an average particle diameter of 0.01 μm to 1 μm.

8. The flux agent of claim 1, further comprising a catalyst, wherein the catalyst includes one or more selected from the group consisting of 1,5,7-triazabicyclo[4.4.0]dec-5-ene, 2-methylimidazole, 1-methylimidazole, zinc acetate, triphenylphosphine, dibutyl phosphate, and a combination thereof.

9. A semiconductor package comprising:
a semiconductor substrate comprising an upper surface and a lower surface which are opposite to each other;
a semiconductor chip including a first surface and a second surface which are opposite to each other, and disposed on the upper surface of the semiconductor substrate, wherein the first surface faces the upper surface of the semiconductor substrate; and
a plurality of protective patterns interposed between the semiconductor substrate and the semiconductor chip, wherein each of the plurality of protective patterns is a cured product of a flux agent,
wherein the flux agent comprises:
a first compound comprising an ester group and an epoxy group;
a fourth compound which is a chemical reactant of a second compound comprising an epoxy group and a third compound comprising an amine group and a carboxyl group; and
a photoinitiator,
wherein:
the content of the first compound is 60 wt % to 95 wt % based on 100 wt % of the flux agent;
the content of the fourth compound is 3 wt % to 33 wt % based on 100 wt % of the flux agent; and
the content of the photoinitiator is 2 wt % to 10 wt % based on 100 wt % of the flux agent.

10. The semiconductor package of claim 9, further comprising:
a plurality of first conductive pads on the upper surface of the semiconductor substrate;
a plurality of second conductive pads on the first surface of the semiconductor chip; and
a plurality of connecting bumps interposed between the plurality of first conductive pads and the plurality of second conductive pads, wherein each of the plurality of protective patterns covers a side surface of a corresponding connecting bump among the plurality of connecting bumps.

11. The semiconductor package of claim 9, wherein each of the plurality of protective patterns is in contact with the upper surface of the semiconductor substrate.

12. The semiconductor package of claim 9, wherein each of the plurality of protective patterns covers a side surface of a corresponding first conductive pad among the plurality of first conductive pads and a side surface of a corresponding second conductive pad among the plurality of second conductive pads.

13. The semiconductor package of claim 9, wherein each of the plurality of protective patterns is in contact with the first surface of the semiconductor chip.

14. The semiconductor package of claim 9, further comprising a molding film disposed on the semiconductor substrate, and covering the semiconductor chip and the plurality of protective patterns.

15. The semiconductor package of claim 14, wherein the plurality of protective patterns are spaced apart from each other in a first direction, and the molding film fills a space between the plurality of protective patterns, wherein the first direction is a direction parallel to the upper surface of the semiconductor substrate.

16. The semiconductor package of claim 9, wherein a width in a first direction of each of the plurality of protective patterns is smaller than a width in the first direction of the semiconductor chip, wherein the first direction is a direction parallel to the upper surface of the semiconductor substrate.

17. The semiconductor package of claim 9, wherein a width in a first direction of each of the plurality of protective patterns decreases in a third direction farther from the upper surface of the semiconductor substrate, wherein the first direction is a direction parallel to the upper surface of the semiconductor substrate, wherein the third direction is a direction perpendicular to the upper surface of the semiconductor substrate.

18. The semiconductor package of claim 9, wherein the first compound and the second compound each comprise at least one of glycidyl epoxy and cyclohexene oxide.

19. A semiconductor package comprising:
a semiconductor substrate including an upper surface and a lower surface which are opposite to each other;
a plurality of first conductive pads on the upper surface of the semiconductor substrate;
a semiconductor chip comprising a first surface and a second surface which are opposite to each other, and disposed on the upper surface of the semiconductor substrate, wherein the first surface faces the upper surface of the semiconductor substrate;
a plurality of second conductive pads on the first surface of the semiconductor chip;
a plurality of connecting bumps interposed between the plurality of first conductive pads and the plurality of second conductive pads; and
a plurality of protective patterns covering the plurality of connecting bumps, wherein a width in a first direction of each of the plurality of protective patterns decreases in a third direction farther from the upper surface of the semiconductor substrate, wherein the first direction is a direction parallel to the upper surface of the semiconductor substrate, wherein the third direction is a direction perpendicular to the upper surface of the semiconductor substrate.

20. The semiconductor package of claim 19, wherein each of the plurality of protective patterns is a cured product of a flux agent,
wherein the flux agent comprises:
a first compound including an ester bond and an epoxy group;
a fourth compound which is a chemical reactant of a second compound including an epoxy group and a third compound including an amine group and a carboxyl group; and
a photoinitiator.
